(19) United States
(12) Patent Application Publication
(10) Pub. No.: US 2025/0203246 A1
(43) Pub. Date: Jun. 19, 2025

(54) IMAGE SENSOR AND DRIVING METHOD THEREOF

(71) Applicant: Samsung Electronics Co., Ltd., Suwon-si (KR)

(72) Inventors: YOUNGGU JIN, Suwon-si (KR); Joongseok Park, Suwon-si (KR)

(21) Appl. No.: 18/925,220

(22) Filed: Oct. 24, 2024

(30) Foreign Application Priority Data
Dec. 15, 2023 (KR) 10-2023-0183428

(51) Int. Cl. H04N 25/78; H01L 27/146; H04N 25/59

(52) U.S. Cl. CPC H04N 25/78; H04N 25/59; H10F 39/18; H10F 39/8037

(57) ABSTRACT

An image sensor comprising a pixel that includes a photoelectric element configured to generate photo charges, a driving transistor configured to generate a pixel signal based on voltage of a first node connected to the photoelectric element, a charge storage element connected to the photoelectric element and configured to store the photo charges, a second transmission transistor connected between the first node and a second node, a first transmission transistor connected between the second node and the photoelectric element, and a first switch transistor connected between the second node and the charge storage element, and a row driver connected to the pixel and configured to control the pixel.

### CROSS-REFERENCE TO RELATED APPLICATION

This application is based on and claims priority under 35 U.S.C. § 119 to Korean Patent Application No. 10-2023-0183428 filed in the Korean Intellectual Property Office on Dec. 15, 2023, the entire contents of which is incorporated herein by reference.

### BACKGROUND

### (a) Field

The present disclosure relates to an image sensor and a driving method thereof.

### (b) Description of the Related Art

Image sensors are devices for capturing two-dimensional or three-dimensional images of objects. Image sensors generate images of objects, using photoelectric conversion elements that react according to the intensity of light reflected from the objects. With the recent development of complementary metal-oxide semiconductor (CMOS) technology, CMOS image sensors using CMOS are being widely used.

Recently, in order to increase the dynamic range of image sensors, image sensors including a plurality of photoelectric elements with different sensitivities are being developed. However, there is a problem that various optical problems may occur due to different optical centers, which are caused by differences in positions between a plurality of photoelectric elements.

### SUMMARY

An image sensor comprising a pixel including a photoelectric element configured to generate photo charges, a driving transistor configured to generate a pixel signal based on a voltage of a first node connected to the photoelectric element, a charge storage element connected to the photoelectric element and configured to store the photo charges, a second transmission transistor connected between the first node and a second node, a first transmission transistor connected between the second node and the photoelectric element, and a first switch transistor connected between the second node and the charge storage element, and a row driver connected to the pixel and configured to control the pixel.

An image sensor comprising a photoelectric element region in which a photoelectric element configured to generate photo charges by being exposed to light during a first time period is disposed, a first transmission transistor region disposed in the photoelectric element region and configured to receive the photo charges, a first selection transistor region configured to receive the photo charges through the first transmission transistor region, and a third transmission transistor region configured to receive the photo charges through the first transmission transistor region, where, during the first time period, the photo charges are alternately transferred to the first selection transistor region and the third transmission transistor region.

A driving method of an image sensor comprising alternately performing a first operation of transferring photo charges of a photoelectric element generated during a first period to a charge storage element and a second operation of transferring photo charges of the photoelectric element generated during a second period after the first period to a first node, generating a first pixel signal based on a voltage of the first node, and generating a second pixel signal based on a voltage of the charge storage element.

### BRIEF DESCRIPTION OF THE DRAWINGS

FIG. 1 is a block diagram illustrating an image sensor according to an embodiment.

FIG. 2 is a circuit diagram of a pixel.

FIG. 3 is a timing diagram showing an operation of a pixel according to FIG. 2.

FIG. 4 is a cross-sectional view showing an image sensor including a pixel according to FIG. 2.

FIG. 5 is a circuit diagram of a pixel according to an embodiment.

FIG. 6 is a timing diagram showing an operation of a pixel according to FIG. 5.

FIG. 7 is a drawing showing a change of potential level in a pixel according to FIG. 5.

FIG. 8 is a timing diagram showing an operation of a pixel according to FIG. 5.

FIG. 9 is a drawing showing a change of potential level in a pixel according to FIG. 5.

FIG. 10 is a circuit diagram of a pixel according to an embodiment.

FIG. 11 is a drawing showing a change of potential level in a pixel according to FIG. 10.

FIG. 12 is a schematic top view of a layout of a pixel according to FIG. 5.

FIG. 13 is a cross-sectional view showing an image sensor taken along line A-A′ of FIG. 12.

FIG. 14 is a schematic top view of a layout of a pixel according to FIG. 5.

FIG. 15 is a schematic top view of a layout of a pixel according to FIG. 5.

FIG. 16 is a schematic top view of a layout of a pixel according to FIG. 5.

FIG. 17 is a circuit diagram of a pixel according to an embodiment.

FIG. 18 is a circuit diagram of a pixel according to an embodiment.

FIG. 19 is a timing diagram showing an operation of a pixel according to FIG. 18.

FIG. 20 is a circuit diagram of a pixel according to an embodiment.

FIG. 21 is a timing diagram showing an operation of a pixel according to FIG. 20.

FIG. 22 is a block diagram showing a vehicle according to an embodiment.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms can be comprehended as the singular forms or plural forms unless clear expressions such as “a”, “an”, or “single” are used. Terms including an ordinal number, such as first and second, are used for describing various constituent elements, but the constituent elements are not limited by the terms. The terms are used only to discriminate one constituent element from other constituent elements.

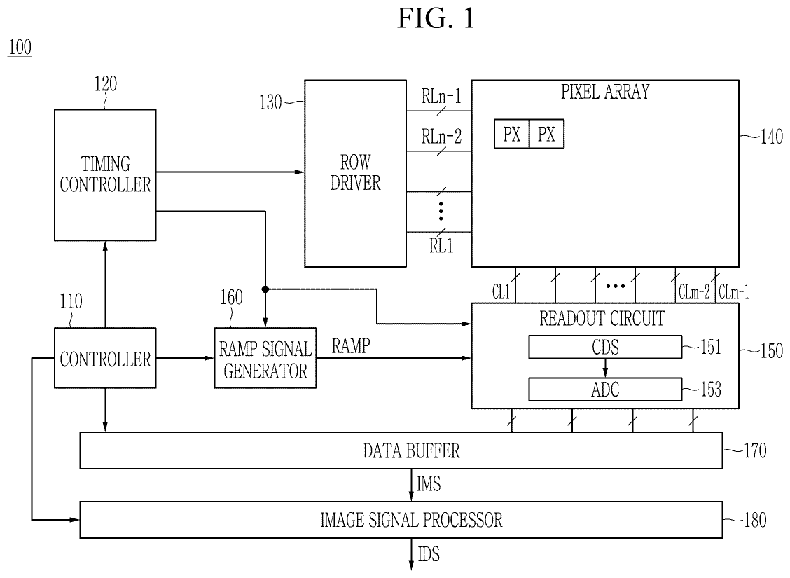

FIG. 1 is a block diagram illustrating an image sensor according to an embodiment. As shown in FIG. 1, an image sensor 100 according to an embodiment may include

a controller 110, a timing controller 120, a row driver 130, a pixel array 140, a readout circuit 150, a ramp signal generator 160, a data buffer 170, and an image signal processor 180. In an embodiment, the image signal processor 180 may be located outside the image sensor 100.

The image sensor 100 may generate an image signal IMS by converting light received from the outside into an electrical signal. The image signal IMS may be provided to the image signal processor 180.

The image sensor 100 may be mounted in an electronic device having an image or light sensing function. For example, the image sensor 100 may be mounted in electronic devices such as cameras, smart phones, wearable devices, IoT (Internet of Things) devices, home appliances, tablet PCs (personal computers), personal digital assistants (PDAs), portable multimedia players (PMPs) navigation devices, drones, advanced drivers assistance systems (ADASs), etc. Also, the image sensor 100 may be mounted in electronic devices which are incorporated as components in vehicles, furniture, manufacturing equipment, doors, various measuring devices, etc.

The controller 110 may generally control each of components 120, 130, 140, 150, 160, 170, and 180 included in the image sensor 100. The controller 110 may control operation timing of each of the components 120, 130, 140, 150, 160, 170, and 180 by using control signals.

In an embodiment, the controller 110 may control the ramp signal generator 160 to adjust a reference signal RAMP generated by the ramp signal generator 160. In an embodiment, the controller 110 may control a timing controller 120 to adjust floating diffusion (FD) capacitance of a pixel circuit within the pixel array 140 through the row driver 130. In an embodiment, the controller 110 may control the timing controller 120 to adjust operation timing of elements within the pixel array 140 through the row driver 130.

The timing controller 120 may generate a signal which is a reference for the operation timings of the components of the image sensor 100. The timing controller 120 may control the timings of the row driver 130, the readout circuit 150, and the ramp signal generator 160. The timing controller 120 may provide a control signal to control the timings of the row driver 130, the readout circuit 150, and the ramp signal generator 160.

The timing controller 120 may control timing of elements within a pixel PX in a reset period, an integration period, and a readout period. The reset period may be a period in which the charges accumulated in floating diffusion nodes within the pixel PX are reset. The integration period may be a period in which the photoelectric element is exposed to light to generate photo charges. The readout period may be a period in which the photo charges generated in the photoelectric element are transferred to the readout circuit 150.

In an embodiment, the controller 110 may control the timing controller 120 such that the photo charges generated by the photoelectric element during the integration period may be distributed to a plurality of floating diffusion nodes connected to the photoelectric element. For example, the controller 110 may control the timing controller 120 such that, during a first period within the integration period, the photo charges are transferred to a first floating diffusion node, and during a second period within the integration period, the photo charges are transferred to a second floating diffusion node. At this time, the first period and the second period in the integration period may be alternately positioned.

The pixel array 140 may include the plurality of pixels PX, and a plurality of row lines RL and a plurality of column lines CL that are coupled to the plurality of pixels PX, respectively. In an embodiment, each pixel PX may include at least one photoelectric element (also referred to as optical sensing device). The photoelectric elements may detect incident light, and convert the incident light into electrical signals based on the amount of light, i.e., a plurality of analog pixel signals. The levels of analog pixel signals which are output from the photoelectric elements may increase as the amounts of charge which are output from the photoelectric elements increase. In other words, the levels of analog pixel signals which are output from the photoelectric elements may increase as the amount of light entering the pixel array 140 increases.

The plurality of row lines RL (RL1 to RLn−1) may extend in a first direction, and be coupled to pixels PX arranged along the first direction. For example, the plurality of row lines RL may transmit control signals output from the row driver 130 to elements included in the pixels PX, for example, transistors. Signal lines other than the row lines RL may be arranged in the first direction. The plurality of column lines CL (CL1 to CLm−1) may extend in a second direction intersecting the first direction, and be coupled to pixels PX arranged along the second direction. The column lines CL may transmit pixel signals output from the pixels PX to the readout circuit 150.

The row driver 130 may generate a control signal for driving the pixel array 140, in response to a control signal from the timing controller 120, and provide the control signal to the plurality of pixels PX of the pixel array 140 through the plurality of row lines RL. In an embodiment, the row driver 130 may control the pixels PX in row line units, such that the pixels detect incident light. Each row line unit may include at least one row line RL.

The readout circuit 150 may convert pixel signals (or electrical signals) received from pixels PX coupled to a selected row line RL among the plurality of pixels PX, into pixel values indicating the amounts of light, in response to a control signal from the timing controller 120. The readout circuit 150 may include a correlated double sampling (CDS) circuit 151, and an analog-digital converter (ADC) circuit 153.

The correlated double sampling (CDS) circuit 151 may include a plurality of comparators, and each comparator may compare the pixel signal received from the pixel array 140 through the plurality of column lines CL with the reference signal RAMP from the ramp signal generator 160. Specifically, the correlated double sampling circuit 151 may compare the received pixel signal with the reference signal RAMP, and may output the comparison result to the analog digital conversion circuit 153.

A plurality of pixel signals output from the plurality of pixels PX may have deviations due to the unique characteristics of each pixel (e.g., fixed pattern noise (FPN), or the like) and/or deviations due to differences in characteristics of pixel circuits for outputting pixel signals from the pixel PX (e.g., transistors for outputting charges stored in photoelectric conversion device within a pixel). In order to compensate for the deviation between the plurality of pixel signals output through the plurality of column lines CL, obtaining a reset component (e.g., a reset voltage) and sensing component (e.g., a sensing voltage) for a pixel signal and extracting the difference (e.g., the difference between the reset voltage and the sensing voltage) as a signal component is called correlated double sampling. The correlated double sampling circuit 151 may output a comparison result in which the correlated double sampling technique is applied with respect to the received pixel signal.

The analog digital conversion circuit 153 may convert the comparison result of the correlated double sampling circuit 151 to digital data, and thereby may generate and output pixel values corresponding to a plurality of pixels, on a row-by-row basis. The analog digital conversion circuit 153 may include a plurality of counters. The counter may be implemented as an up-counter and a calculation circuit, or up/down counters, or a bit-wise inversion counter, in which the count value sequentially increases based on a counting clock signal. The plurality of counters may be connected to the outputs of the plurality of comparators, respectively. Each of the plurality of counters may count the comparison result output from a corresponding comparator, and may output a digital data (e.g., pixel value) according to the counting result.

The ramp signal generator 160 may generate a reference signal RAMP and transmit it to the readout circuit 150. The ramp signal generator 160 may include current sources, resistors, and capacitors. The ramp signal generator 160 may adjust ramp voltage which is voltage to be applied to a ramp resistor by adjusting the current magnitude of a variable current source or the resistance value of a variable resistor. In this way, the ramp signal generator may generate a plurality of ramp signals which falls or rise at slopes determined depending on the current magnitudes of variable current sources or the resistance values of variable resistors.

The data buffer 170 may store the pixel values of the plurality of pixels PX coupled to the selected column line CL, received from the readout circuit 150. The data buffer 170 may output the pixel value stored in response to an enable signal from the controller 110 to the image signal processor 180 as the image signal IMS.

The image signal processor 180 may perform image signal processing on image signals IMSs received from the data buffer 170. For example, the image signal processor 180 may receive a plurality of image signals IMS from the data buffer 170, and synthesize the received image data IDS to generate one image.

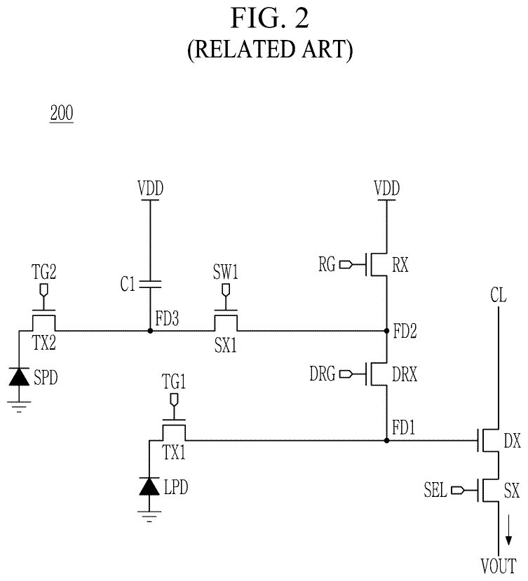

FIG. 2 is a circuit diagram of a conventional pixel PX.

Referring to FIG. 2, a pixel 200 may include a plurality of photoelectric elements, for example, a small photoelectric element SPD and a large photoelectric element LPD. The pixel 200 may include a plurality of transistors, for example a first transmission transistor TX1, a second transmission transistor TX2, a reset transistor RX, a driving a transistor DX, a selection transistor SX, a gain control transistor DRX, a first switch transistor SX1, and a first capacitor C1. Control signals TG1, TG2, RG, SEL, DRG, and SW1 may be applied to the pixel 200. In an embodiment, the control signals may be generated by the row driver 130 (refer to FIG. 1) based on the control of the timing controller 120.

The large photoelectric element LPD and the small photoelectric element SPD may variably generate photo charges depending on the intensity of light. For example, the large photoelectric element LPD and the small photoelectric element SPD may generate charges in proportion to an amount of indent light. The photo charges generated by the large photoelectric element LPD and the small photoelectric element SPD may be transmitted to and accumulated in at least one of a first floating diffusion node FD1, a second floating diffusion node FD2, and a third floating diffusion node FD3. Although not shown in FIG. 2, in each of the first floating diffusion node FD1, the second floating diffusion node FD2, and the third floating diffusion node FD3 each, a parasitic capacitor (not shown) may be formed, or an actual capacitor element may be connected thereto.

The first transmission transistor TX1 may be connected between the large photoelectric element LPD and the first floating diffusion node FD1. The first transmission transistor TX1 may be controlled by a first transmission control signal TG1. When the first transmission transistor TX1 is turned on, the charge generated by the large photoelectric element LPD may be transferred to the first floating diffusion node FD1.

The second transmission transistor TX2 may be connected between the small photoelectric element SPD and the second floating diffusion node FD2. The second transmission transistor TX2 may be controlled by a second transmission control signal TG2. When the second transmission transistor TX2 is turned on, the charge generated by the small photoelectric element SPD may be transferred to the floating diffusion node FD2.

The reset transistor RX may be connected between the second floating diffusion node FD2 and a power source voltage line supplying a power source voltage VDD. The reset transistor RX may be controlled by a reset control signal RG. When the reset transistor RX is turned on, the power source voltage VDD may be applied to the second floating diffusion node FD2, and thereby the second floating diffusion node FD2 may be reset. When a switch transistor SW1 is turned on while the reset transistor RX is turned on, the third floating diffusion node FD3 and the second floating diffusion node FD2 may be reset to the power source voltage. When the gain control transistor DRX is turned on while the reset transistor RX is turned on, the first floating diffusion node FD1 and the second floating diffusion node FD2 may be reset to the power source voltage.

A gate of the driving transistor DX may be connected to the first floating diffusion node FD1. A first terminal of the driving transistor DX may be connected to the selection transistor SX, and a driving voltage may be applied to a second terminal thereof. The driving transistor DX may operate as a source-follower amplifier with respect to a voltage of the first floating diffusion node FD1. In response to the voltage of the first floating diffusion node FD1, the driving transistor DX may output a pixel signal VOUT to the column line CL through the selection transistor SX.

The selection transistor SX may be connected to the column line CL and first terminal of the driving transistor DX, and may be controlled by a selection control signal SEL. When the selection transistor SX is turned on, a pixel voltage VOUT output from the driving transistor DX may be output to the readout circuit 150 (refer to FIG. 1) through the column line CL connected to the selection transistor SX. For example, when the selection transistor SX is turned on in the readout operation, a pixel signal including a reset signal corresponding to a reset operation or an image signal corresponding to a charge accumulation operation may be output through the column line CL.

The gain control transistor DRX may be connected between the first floating diffusion node FD1 and the second floating diffusion node FD2. The gain control transistor DRX may be controlled by a gain control signal DRG. When the gain control transistor DRX is turned on, the first floating diffusion node FD1 and the second floating diffusion node FD2 are connected to each other such that the capacitance may increase, and a conversion gain, which is a ratio of charges converted to voltage may decrease. That is, when the gain control transistor DRX is turned on, a low conversion gain (LCG) mode may operate. To the contrary, when the gain control transistor DRX is turned off, a high conversion gain (HCG) mode may operate.

The first switch transistor SX1 may be connected between the second floating diffusion node FD2 and the third floating diffusion node FD3. In response to a first switch control signal SW1, the first switch transistor SX1 may be turned on or turned off, and may interconnect the second floating diffusion node FD2 and the third floating diffusion node FD3.

The first capacitor C1 may be connected between the third floating diffusion node FD3 and the power source voltage line supplying the power source voltage VDD. When the first switch transistor SX1 is turned on, the second floating diffusion node FD2 and the third floating diffusion node FD3 are interconnected, and the first capacitor C1 may be coupled in parallel with the parasitic capacitor formed at the second floating diffusion node FD2. Accordingly, the capacitance of the second floating diffusion node FD2 may increase. That is, the first capacitor C1 may be used to adjust the capacitance of the second floating diffusion node FD2. In an embodiment, the photo charges generated by the small photoelectric element SPD during the integration period may overflow, and the overflowed charge may be accumulated in the first capacitor C1 via the third floating diffusion node FD3.

The first capacitor C1 may include a lateral overflow integration capacitor (LOFIC). When the first capacitor C1 includes the LOFIC, overflowed charges among charges transferred from the small photoelectric element SPD and/or the large photoelectric element LPD to the first floating diffusion node FD1 may be stored. That is, a large amount of charge that overflows may be integrated into the first capacitor C1 without being discarded.

According to an embodiment, the large photoelectric element LPD may generate pixel signals corresponding to a dual conversion gain (DCG) through the gain control transistor DRX. Specifically, the gain control transistor DRX may be turned on or turned off according to the gain control signal DRG, and thereby pixel signals corresponding to DCG may be obtained with respect to the large photoelectric element LPD.

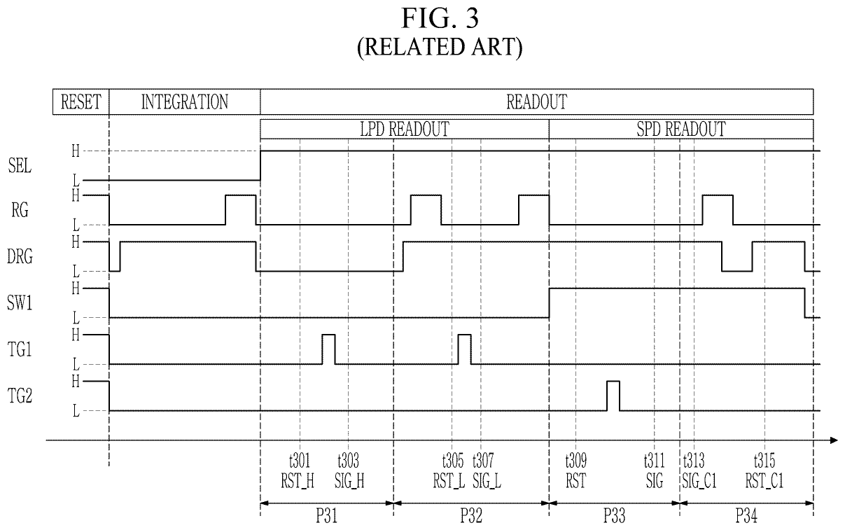

FIG. 3 is a timing diagram showing an operation of a pixel according to FIG. 2.

In FIG. 3, a scan period for driving the plurality of pixels PX on a row line basis may be shown. One scan period may sequentially include a reset period RESET, an integration period INTEGRATION, a readout period READOUT.

In the reset period RESET, charges stored in the first floating diffusion node FD1, the second floating diffusion node FD2, and the third floating diffusion node FD3 may be reset.

In more detail, in the reset period RESET, the reset control signal RG, the gain control signal DRG, the first switch control signal SW1, the first transmission control signal TG1, and the second transmission control signal TG2 may all have a high-level H. Accordingly, the first floating diffusion node FD1, the second floating diffusion node FD2, and the third floating diffusion node FD3 may all be reset to the power source voltage VDD.

The integration period INTEGRATION is a period in which the small photoelectric element SPD and the large photoelectric element LPD are exposed to light and thereby charges are generated. In the integration period INTEGRATION, the reset control signal RG, the gain control signal DRG, the first switch control signal SW1, the first transmission control signal TG1, and the second transmission control signal TG2 may transition to a low-level L.

Meanwhile, the gain control signal DRG may become the high-level H again after a preset time. While the gain control signal DRG maintains the high-level H, the reset control signal RG may transition from the low-level L to the high-level H. According to the gain control signal DRG and the reset control signal RG of the high-level H, the first floating diffusion node FD1 and the second floating diffusion node FD2 may be reset to the power source voltage.

Thereafter, the reset control signal RG and the gain control signal DRG may transition from the high-level H to the low-level L. As the reset control signal RG transitions to the low-level L, the selection control signal SEL may transition from the low-level L to the high-level H.

The readout period READOUT is a period in which the pixel signal VOUT generated by the pixel 200 is transferred to the readout circuit 150 (refer to FIG. 1). One readout period READOUT may include a LPD readout period LPD READOUT to read out the pixel signals corresponding to the large photoelectric element LPD and a SPD readout period SPD READOUT to read out the pixel signals corresponding to the small photoelectric element SPD.

The LPD readout period LPD READOUT may include a first period P31 and a second period P32. The first period P31 may be a period for performing an HCG operation with respect to the large photoelectric element LPD. The second period P32 may be a period for performing an LCG operation with respect to the large photoelectric element LPD.

First, at t301, according to the gain control signal DRG of the low-level L, the first floating diffusion node FD1 is not connected to the second floating diffusion node FD2, and accordingly, the pixel 200 may operate in the high conversion gain (HCG) mode. A reset signal corresponding to the reset first floating diffusion node FD1 may be output through the column line CL. That is, at t301, a reset signal RST_H of the high conversion gain (HCG) mode with respect to the large photoelectric element LPD may be output as the pixel signal VOUT.

After t301, the first transmission control signal TG1 may transition from the low-level L to the high-level H. According to the first transmission control signal TG1 of the high-level H, the charges generated by the large photoelectric element LPD may be provided to the first floating diffusion node FD1.

At t303, an image signal corresponding to the first floating diffusion node FD1 may be output through the column line CL. At this time, the gain control signal DRG may maintain the low-level L, and the second floating diffusion node FD2 is not connected to the first floating diffusion node FD1, and accordingly, the pixel 200 may operate in the high conversion gain (HCG) mode. That is, at t303, an image signal SIG_H of the high conversion gain (HCG) mode with respect to the large photoelectric element LPD may be output as the pixel signal VOUT.

After t303, the gain control signal DRG may transition from the low-level L to the high-level H. In addition, the reset control signal RG may transition from the low-level L to the high-level H. According to the reset control signal RG and the gain control signal DRG of the high-level H, the first floating diffusion node FD1 and the second floating diffusion node FD2 may be reset to the power source voltage. Thereafter, the reset control signal RG may be transitioned to the low-level L.

At t305, a reset signal corresponding to the reset first floating diffusion node FD1 and the second floating diffusion node FD2 may be output through the column line CL. At this time, the gain control signal DRG may maintain the high-level H, and since the second floating diffusion node FD2 is connected to the first floating diffusion node FD1, the pixel 200 may operate in the low conversion gain (LCG) mode. That is, at t305, a reset signal RST_L of the low conversion gain (LCG) mode with respect to the large photoelectric element LPD may be output as the pixel signal VOUT.

After t305, the first transmission control signal TG1 may transition from the low-level L to the high-level H. According to the first transmission control signal TG1 of the high-level H, the charges generated by the large photoelectric element LPD may be provided to the first floating diffusion node FD1 and the second floating diffusion node FD2.

At t307, an image signal corresponding to the first floating diffusion node FD1 and the second floating diffusion node FD2 may be output through the column line CL. At this time, since the gain control signal DRG maintains the low-level L, the pixel 200 may operate in the low conversion gain (LCG) mode. That is, at t307, the image signal SIG_L of the low conversion gain (LCG) mode with respect to the large photoelectric element LPD may be output as the pixel signal VOUT.

After t307, the reset control signal RG may transition from the low-level L to the high-level H. According to the reset control signal RG of the high-level H, the first floating diffusion node FD1 and the second floating diffusion node FD2 may be reset to the power source voltage. Accordingly, the charges remaining after outputting pixel signals of the large photoelectric element LPD may be removed. Thereafter, the reset control signal RG may be transitioned to the low-level L.

The SPD readout period SPD READOUT may include a third period P33 and a fourth period P34. The third period P33 may be a period for performing a CDS operation with respect to the small photoelectric element SPD. The fourth period P34 may be a period for performing a CDS operation with respect to overflowed charges with respect to the small photoelectric element SPD.

First, the gain control signal DRG may maintain the high-level H. The first switch control signal SW1 may transition from the low-level L to the high-level H. According to the first switch control signal SW1 of the high-level H, the second floating diffusion node FD2 may be connected to the third floating diffusion node FD3.

At t309, a reset signal corresponding to the reset second floating diffusion node FD2 and the third floating diffusion node FD3 may be output through the column line CL. That is, at t309, the reset signal RST with respect to the small photoelectric element SPD may be output as the pixel signal VOUT.

After t309, the second transmission control signal TG2 may transition from the low-level L to the high-level H. According to the second transmission control signal TG2 of the high-level H, the charges generated by the small photoelectric element SPD may be provided to the first floating diffusion node FD1, the second floating diffusion node FD2, and the third floating diffusion node FD3.

At t311, an image signal correspond to the first floating diffusion node FD1, the second floating diffusion node FD2, and the third floating diffusion node FD3 may be output through the column line CL. That is, at t311, the image signal SIG with respect to the small photoelectric element SPD may be output as the pixel signal VOUT.

Meanwhile, the charge overflowed from the small photoelectric element SPD by the exposure operation may be accumulated in the first capacitor C1. At t313, an image signal corresponding to the first capacitor C1 may be output through the column line CL. That is, at t313, the output pixel signal is an image signal SIG_C1 with respect to overflowed charges of the small photoelectric element SPD.

After t313, the reset control signal RG may transition from the low-level L to the high-level H. At this time, since the gain control signal DRG is at the high-level H and the switch control signal SW1 also maintains the high-level H, the first floating diffusion node FD1, the second floating diffusion node FD2, and the third floating diffusion node FD3 may be reset. Thereafter, the gain control signal DRG may transition from the high-level H to the low-level L. At this time, since the switch control signal SW1 maintains the high-level H, the charges accumulated in the first capacitor C1 may also be reset. While the gain control signal DRG maintains the low-level L, the reset control signal RG may transition to the low-level L. Thereafter, the gain control signal DRG may transition from the low-level L to the high-level H.

At t315, a reset signal corresponding to the reset first floating diffusion node FD1, the second floating diffusion node FD2, and the third floating diffusion node FD3 may be output through the column line CL. That is, at t315, a reset signal RST_C1 with respect to the overflowed charges of the small photoelectric element SPD may be output as the pixel signal VOUT.

The pixel 200 may sequentially output the reset signal RST_H and the image signal SIG_H of the high conversion gain (HCG) mode with respect to the large photoelectric element LPD, the reset signal RST_L and the image signal SIG_L of the low conversion gain (LCG) mode with respect to the large photoelectric element LPD, the reset signal RST and the image signal SIG with respect to the small photoelectric element SPD, and the reset signal RST_C1 and the image signal SIG_C1 with respect to the overflowed charges of the small photoelectric element SPD. Meanwhile, the present disclosure is not limited thereto, and the image sensor may read the signal of the pixel 200 through an appropriate readout operation.

Meanwhile, in FIG. 3, although it is described that a plurality of transistors are enabled when a signal of the high-level His applied, the present disclosure is not limited thereto, and any transistor may be configured to be enabled when a signal of the low-level L is applied.

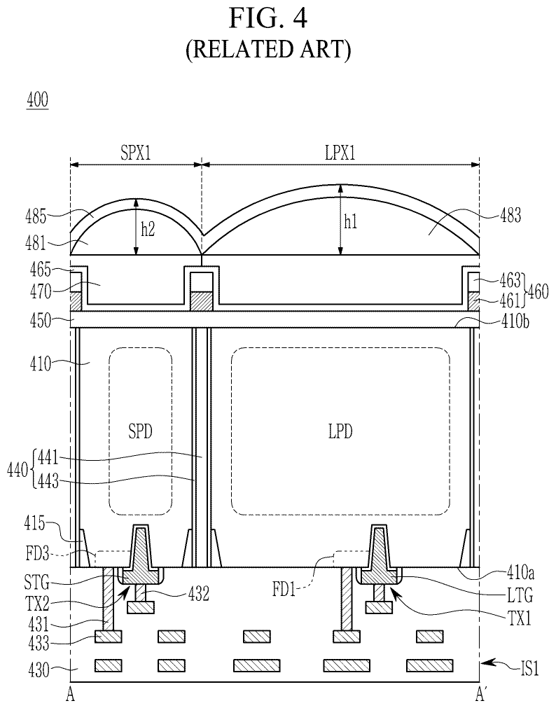

FIG. 4 is a cross-sectional view showing an image sensor including a pixel according to FIG. 2.

An image sensor 400 may include a first substrate 410, the large photoelectric element LPD, the small photoelectric element SPD, an isolation layer 415, a pixel separation pattern 440, a surface insulation layer 450, a grid pattern 460, a first protective layer 465, a color filter 470, microlenses 481 and 483 and a second protective layer 485.

The first substrate 410 may include a first surface 410a and a second surface 410b that are opposite to each other. In an embodiment, the first surface 410a may be referred to as a front side of the first substrate 410, and the second surface 410b may be referred to as a back side of the first substrate 410. In an embodiment, the second surface 410b of the first substrate 410 may be a light receiving surface on which the light is incident. That is, an image sensor according to an embodiment may be a back side illuminated (BSI) image sensor.

The first substrate 410 may be a semiconductor substrate. For example, the first substrate 410 may be bulk silicon or silicon-on-insulator (SOI). Alternatively, the first substrate 410 may include a base substrate on which an epitaxial layer is formed.

In an embodiment, the first substrate 410 may have a first conductivity type. For example, the first substrate 410 may include p-type impurities (e.g., boron (B)). In an embodiment, the first conductivity type is assumed to be p-type, but the present disclosure is not limited thereto, and the first conductivity type may be n-type.

A first pixel LPX1 and a second pixel SPX1 may be located on the first substrate 410. The large photoelectric element LPD may be located within the first substrate 410 of the first pixel LPX1. The small photoelectric element SPD may be located within the first substrate 410 of a second pixel LPX2. The large photoelectric element LPD and the small photoelectric element SPD may have a second conductivity type different from the first conductivity type. In an embodiment, the second conductivity type is assumed to be n-type, but the present disclosure is not limited thereto, and the second conductivity type may be p-type. The large photoelectric element LPD and the small photoelectric element SPD may be formed, for example, by ion-implantation of n-type impurities (e.g., phosphorus (P) or arsenic (As)) into the p-type first substrate 410.

In an embodiment, the large photoelectric element LPD and the small photoelectric element SPD may have a potential gradient in a direction (e.g., vertical direction) crossing the first surface 410a and the second surface 410b of the first substrate 410. For example, impurity concentration of the large photoelectric element LPD and the small photoelectric element SPD may decrease from the first surface 410a toward the second surface 410b.

In an embodiment, in the plan view, an area of the first pixel LPX1 may be larger than an area of the second pixel SPX1. In the plan view, an area of the large photoelectric element LPD may be larger than an area of the small photoelectric element SPD.

A first floating diffusion region FD1 may be located within the first substrate 410 of the first pixel LPX1. The third floating diffusion region FD3 may be located within the first substrate 410 of the second pixel SPX1.

The first floating diffusion region FD1 and third floating diffusion region FD3 may have the second conductivity type. For example, the first floating diffusion region FD1 and third floating diffusion region FD3 may be formed by ion-implantation of n-type impurities into the p-type first substrate 410.

In an embodiment, each of the first floating diffusion region FD1 and third floating diffusion region FD3 may have the second conductivity type at impurity concentration higher than each of the large photoelectric element LPD and the small photoelectric element SPD. For example, the first floating diffusion region FD1 and third floating diffusion region FD3 may be formed by ion-implantation of highly concentrated n-type impurities (n+) into the p-type first substrate 410.

The first transmission transistor TX1 and the second transmission transistor TX2 may be located on the first surface 410a of the first substrate 410. The first transmission transistor TX1 may include a first transfer gate LTG, a first gate insulating layer and a first gate spacer. The first gate insulating layer may be disposed between the first transfer gate LTG and the first substrate 410, and the first gate spacer may be disposed on both sidewalls of the first transfer gate LTG. The second transmission transistor TX2 may include a second transfer gate STG, a second gate insulating layer, and a second gate spacer. The second gate insulating layer may be disposed between the second transfer gate STG and the first substrate 410, and the second gate spacer may be disposed on both sidewalls of the second transfer gate STG. In an embodiment, the first transfer gate LTG and the second transfer gate STG may be a vertical transfer gate. That is, at least a portion of the gate of the first transfer gate LTG and the second transfer gate STG may be buried within the first substrate 410. For example, a trench extending from the first surface 410a of the first substrate 410 may be located within the first substrate 410. At least a portion of the gate of the first transfer gate LTG and the second transfer gate STG may be located to fill the trench. Accordingly, lower surfaces of the first transfer gate LTG and the second transfer gate STG may be disposed within the first substrate 410. In an embodiment, width of the first transfer gate LTG and the second transfer gate STG may decrease away from the first surface 410a of the first substrate 410. This may be due to the characteristics of the etching process for forming the trench.

A first wire structure IS1 may be located on the first substrate 410. The first wire structure IS1 may be located on for example, the first surface 410a of the first substrate 410. In addition, the first wire structure IS1 may cover, for example, the first surface 410a of the first substrate 410.

The first wire structure IS1 may be configured as one or more wires. For example, the first wire structure IS1 may include a first line insulation layer 430 and a plurality of first wires 433, a plurality of first contacts 431, and a plurality of second contacts 432 within the first line insulation layer 430. The number and arrangement of layers of the wires 433 and contacts 431 and 132 constituting the first wire structure IS1 are merely an example, and the present disclosure is not limited thereto.

A first wire 433 may be electrically connected to the first pixel LPX1 and the second pixel SPX1. For example, the first wire 433 may be connected to the first substrate 410 through a first contact 431, and may be connected to the first transfer gate LTG of the first transmission transistor TX1 or the second transfer gate STG of the second transmission transistor TX2 through a second contact 432.

The first line insulation layer 430 may include, for example, at least one of low dielectric constant (low-k) materials having a lower dielectric constant than silicon oxide, silicon nitride, silicon oxynitride and silicon oxide, but is not limited thereto. The first wire 433, the first contact 431 and the second contact 432 may include a conductive material.

The pixel separation pattern 440 may be located to surround the first pixel LPX1 and the second pixel SPX1, in the plan view. The pixel separation pattern 440 may separate the first pixel LPX1 and the second pixel SPX1. The pixel separation pattern 440 may be located within the first substrate 410. The pixel separation pattern 440 may be, for example, buried into a deep trench formed by patterning the first substrate 410.

In an embodiment, the pixel separation pattern 440 may include a conductive filling pattern 441 and an insulation spacer layer 443. The insulation spacer layer 443 may extend along a side surface of the trench within the first substrate 410. The conductive filling pattern 441 may be disposed on the insulation spacer layer 443 and may fill a remaining portion of the trench. The insulation spacer layer 443 may separate the conductive filling pattern 441 from the first substrate 410.

The isolation layer 415 may be located within the first substrate 410. As for the isolation layer 415, for example, an insulating material may be buried within a trench formed by patterning the first substrate 410. The isolation layer 415 may be adjacent to the first surface 410a of the first substrate 410, and may extend from the first surface 410a.

The isolation layer 415 may overlap the pixel separation pattern 440. A portion of the pixel separation pattern 440 may be located within the isolation layer 415. The pixel separation pattern 440 may penetrate the isolation layer 415. The isolation layer 415 may include a insulating material.

The surface insulation layer 450 may be located on the first surface 410a of the first substrate 410. The surface insulation layer 450 may cover the first surface 410a of the first substrate 410. The surface insulation layer 450 may include a insulating material.

The surface insulation layer 450 may function as an anti-reflection layer, and thereby prevent reflection of light incident on the first substrate 410, such that the light reception rate of a photoelectric element 416 may be improved. In addition, the surface insulation layer 450 may function as an planarization layer, and thereby the color filter 470 and microlenses 481 and 483 may be formed in a uniform height.

The color filter 470 may be located on the surface insulation layer 450. The color filter 470 may be arranged to correspond to each of the first pixel LPX1 and the second pixel SPX1.

In an embodiment, the grid pattern 460 may be located between color filters 470. The grid pattern 460 may be located on the surface insulation layer 450. The grid pattern 460 may be formed in a lattice pattern in the plan view, and may be interposed between the color filters 470.

In an embodiment, the grid pattern 460 may include a conductive pattern 461 and a low refractive index pattern 463. The conductive pattern 461 and the low refractive index pattern 463 may be sequentially stacked, for example, on the surface insulation layer 450. The conductive pattern 461 may include a conductive material. The low refractive index pattern 463 may include a low refractive index material having a lower refractive index than silicon (Si). The low refractive index pattern 463 may improve light collection efficiency by refracting or reflecting obliquely incident light, thereby improving the quality of the image sensor.

In an embodiment, the first protective layer 465 may be located on the surface insulation layer 450 and the grid pattern 460.

The first protective layer 465 may include, for example, aluminum oxide, but is not limited thereto. The first protective layer 465 may prevent damage of the surface insulation layer 450 and the grid pattern 460.

The microlenses 481 and 483 may be located on the color filter 470. The microlenses 481 and 483 may each have a convex shape, and may have a predetermined radius of curvature. Accordingly, the microlenses 481 and 483 may collect light incident on the small photoelectric element SPD and the large photoelectric element LPD, respectively. The microlenses 481 and 483 may each include, for example, a light-transmissive resin, but is not limited thereto.

In an embodiment, the second protective layer 485 may be located on the microlenses 481 and 483. The second protective layer 485 may extend along a surface of the microlenses 481 and 483. The second protective layer 485 may include, for example, inorganic material oxide layer. For example, the second protective layer 485 may include at least one of silicon oxide, titanium oxide, zirconium oxide, hafnium oxide, and a combination thereof, but is not limited thereto. In some embodiments, the second protective layer 485 may include low temperature oxide (LTO).

The second protective layer 485 may protect the microlenses 481 and 483 from the outside. For example, the second protective layer 485 may include an inorganic material oxide layer, such that the microlenses 481 and 483 including an organic material may be protected. In addition, the second protective layer 485 may improve the quality of the image sensor by improving light collection efficiency of the microlenses 481 and 483. For example, the second protective layer 485 may decrease reflection, refraction, scattering, etc. of incident light reaching the space between the microlenses 481 and 483, by filling the space between the microlenses 481 and 483.

Meanwhile, as shown in FIG. 4, the microlens 481 of the first pixel LPX1 may have a first height h1, and the microlens 483 of the second pixel SPX may have a second height h2. Meanwhile, as described above, the area of the large photoelectric element LPD may be larger than the area of the small photoelectric element SPD, and accordingly, the area of the first pixel LPX1 may be larger than the area of the second pixel SPX1. In order to cover the second pixel SPX1 having a wider area, the first height h1 of the microlens 483 may be higher than the second height h2 of the microlens 481. Due to difference of lens heights between the first pixel LPX1 and the second pixel SPX1, when light is obliquely incident, the sensitivity ratio may not be fixed but vary. In addition, the large photoelectric element LPD and the small photoelectric element SPD may be disposed at different locations such that optical centers thereof may be different. Accordingly, an error may occur in resolution of color when integrating image signals sensed by the large photoelectric element LPD and the small photoelectric element SPD. Accordingly, the image sensor 400 may experience optical problems such as discrepancy in relative illumination and color separation.

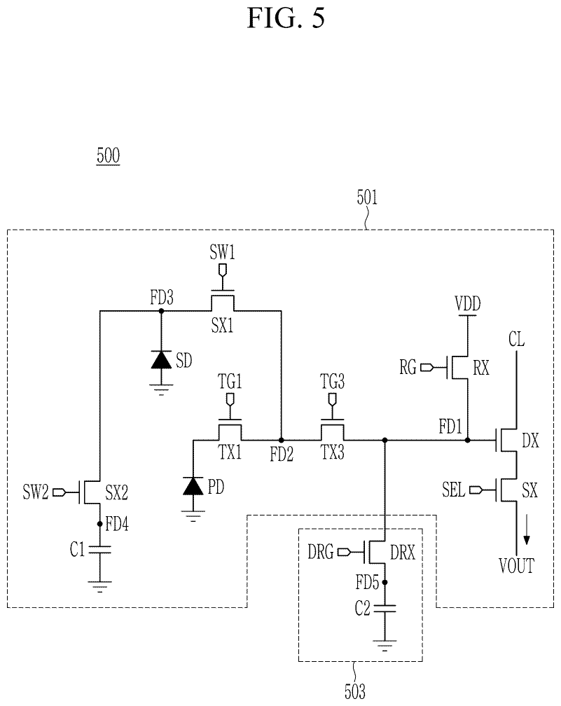

FIG. 5 is a circuit diagram of a pixel according to an embodiment of the present application.

In more detail, FIG. 5 is a circuit diagram of a pixel according to an embodiment of the present application that may be utilized as the pixel PX of FIG. 1. Referring to FIG. 5, a pixel 500 may include a first circuit 501 and a second circuit 503. The first circuit 501 may include a photoelectric element PD. The photoelectric element PD may variably generate photo charges depending on the intensity of light. The photo charges generated by the photoelectric element PD may be transmitted to and accumulated in at least one of floating diffusion nodes FD1, FD2, FD3, FD4, and FD5. Although not shown in FIG. 5, in each of the floating diffusion nodes FD1, FD2, FD3, FD4, and FD5, a parasitic capacitor (not shown) may be formed, or an actual capacitor element may be connected thereto.

In addition, the first circuit 501 may include a plurality of transistors, for example the first transmission transistor TX1, a third transmission transistor TX3, the reset transistor RX, the driving transistor DX, the selection transistor SX, the first switch transistor SX1, a second switch transistor SX2, and the first capacitor C1. The second circuit 503 may include the gain control transistor DRX and a second capacitor C2. Control signals TG1, TG3, RG, SEL, DRG, SW1, and SW2 may be applied to the pixel PX 500. In an embodiment, the control signals may be generated by the row driver 130 (refer to FIG. 1).

The first transmission transistor TX1 may be connected between the photoelectric element PD and the second floating diffusion node FD2. The first transmission transistor TX1 may be controlled by the first transmission control signal TG1. When the first transmission transistor TX1 is turned on, the charge generated by the photoelectric element PD may be transferred to the second floating diffusion node FD2. In an embodiment, even in the state that the first transmission transistor TX1 is turned off, when photo charges are excessively generated by the photoelectric element PD, the excess photo-charges may be transferred to the second floating diffusion node FD2.

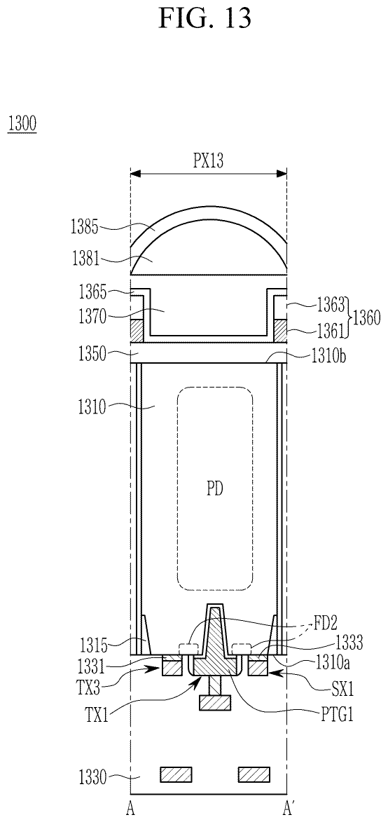

The third transmission transistor TX3 may be connected between the second floating diffusion node FD2 and the first floating diffusion node FD1. The third transmission transistor TX3 may be controlled by a third transmission control signal TG3. Since the second floating diffusion node FD2 is only used as a photo-charge moving path, it may be formed in a low doping concentration or intrinsic state such that the capacity may be formed low. In an embodiment, as will be described later with reference to FIG. 13, the first transmission transistor TX1, the third transmission transistor TX3, and the first switch transistor SX1 may be disposed to be adjacent to each other such that the first circuit 501 may be formed such that the area occupied by the second floating diffusion node FD2 becomes small. The third transmission transistor TX3 may be controlled by the third transmission control signal TG3. When the third transmission transistor TX3 is turned on, charges having reached the second floating diffusion node FD2 may be transferred to the first floating diffusion node FD1.

The reset transistor RX may be connected between the first floating diffusion node FD1 and the power source voltage line supplying the power source voltage VDD. The reset transistor RX may be controlled by the reset control signal RG. When the reset transistor RX is turned on, the power source voltage VDD is applied to the first floating diffusion node FD1, and thus the first floating diffusion node FD1 may be reset to the power source voltage.

The gate of the driving transistor DX may be connected to the first floating diffusion node FD1. The first terminal of the driving transistor DX may be connected to the selection transistor SX, and a driving voltage may be applied to a second terminal thereof. The driving transistor DX may operate as a source-follower amplifier with respect to the voltage of the first floating diffusion node FD1. In response to the voltage of the first floating diffusion node FD1, the driving transistor DX may output the pixel signal VOUT to the column line CL through the selection transistor SX.

The selection transistor SX may be connected to the column line CL and first terminal of the driving transistor DX, and may be controlled by the selection control signal SEL. The selection transistor SX1 may be coupled between the first terminal of the drive transistor DX and the column line CL1, and be controlled by the selection control signal SEL. When the selection transistor SX is turned on, the pixel voltage VOUT output from the driving transistor DX may be output to the readout circuit 150 (refer to FIG. 1) through the column line CL connected to the selection transistor SX. When the selection transistor SX1 is turned on, the pixel voltage VOUT which is output from the drive transistor DX can be output to a readout circuit (reference symbol “150” in FIG. 1) through the column line CL1 coupled to the selection transistor SX1. For example, in the readout operation, when the selection transistor SX is turned on, a pixel signal including the reset signal corresponding to the reset operation or the image signal corresponding to the charge accumulation operation may be output through the column line CL.

The first switch transistor SX1 may be connected between the second floating diffusion node FD2 and the third floating diffusion node FD3. The first switch transistor SX1 may be controlled by the first switch control signal SW1. When the first switch transistor SX1 is turned on, the second floating diffusion node FD2 and the third floating diffusion node FD3 may be connected.

A storage diode SD may be located in the third floating diffusion node FD3. The storage diode SD may be a charge storage element capable of storing the photo charges generated by the photoelectric element PD before transferring it to a fourth floating diffusion node FD4. The cathode of the storage diode SD may become a storage diode region. In an embodiment, the storage diode SD may be additionally located within the semiconductor substrate. In an embodiment, a storage gate for controlling the storage diode SD may be further disposed on the storage diode SD. In an embodiment, the storage diode SD may store a part of photo charges generated by the photoelectric element PD.

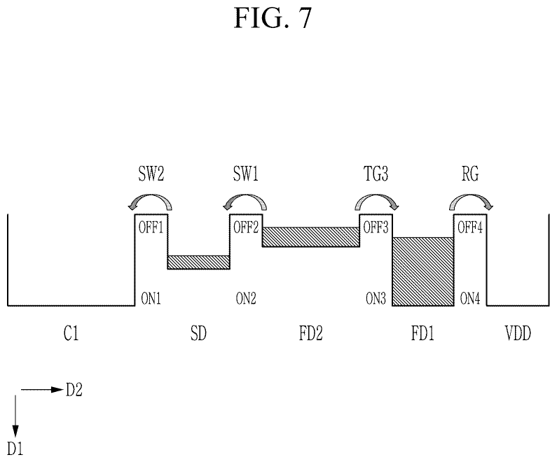

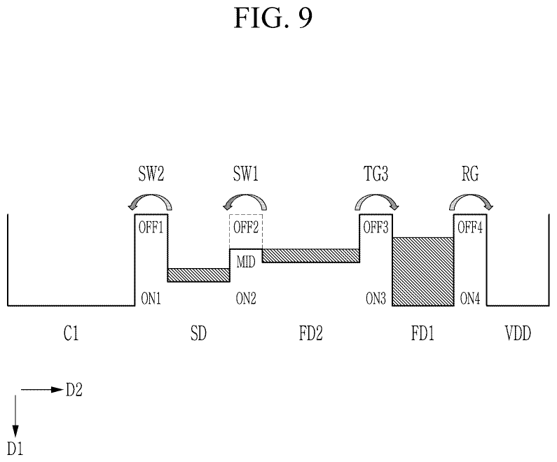

The storage diode SD may be implemented by doping n-type impurities within semiconductor substrate. The amount of charges that may be stored in the storage diode SD is described in detail with reference to FIGS. 7 and 9. However, according to the storage diode SD, the magnitude of the dark current that may be generated while reading the pixel signal is small, and the amount of charges remaining in the storage diode SD when resetting to the power source voltage may be small.

The second switch transistor SX2 may be connected between the third floating diffusion node FD3 and the fourth floating diffusion node FD4. The second switch transistor SX2 may be controlled by a second switch control signal SW2. When the second switch transistor SX2 is turned on, the third floating diffusion node FD3 and the fourth floating diffusion node FD4 may be connected.

The first capacitor C1 may be connected between the fourth floating diffusion node FD4 and ground power source. The power source is not limited to a ground state, and may be a power source of a preset voltage or a variable voltage. The charges generated by the photoelectric element PD may be accumulated in the first capacitor C1 through the second floating diffusion node FD2, the third floating diffusion node FD3, and the fourth floating diffusion node FD4. In an embodiment, the first capacitor C1 may include a lateral overflow integration capacitor (LOFIC).

The gain control transistor DRX may be connected between the first floating diffusion node FD1 and a fifth floating diffusion node FD5. The gain control transistor DRX may be controlled by the gain control signal DRG. The second capacitor C2 may be connected between the fifth floating diffusion node FD5 and ground power source. When the gain control transistor DRX is turned on, the first floating diffusion node FD1 and the fifth floating diffusion node FD5 are connected to each other such that the capacitance may increase, and a conversion gain, which is a ratio of charges converted to voltage may decrease. That is, when the conversion gain transistor DRX is turned on, the low conversion gain (LCG) mode may operate. To the contrary, when the conversion gain transistor DRX is turned off, the high conversion gain (HCG) mode may operate.

Although FIG. 5 illustrates that the pixel 500 includes one second circuit 503, the present disclosure is not limited thereto, and the pixel 500 may not include the second circuit 503, and may include a plurality of second circuits 503.

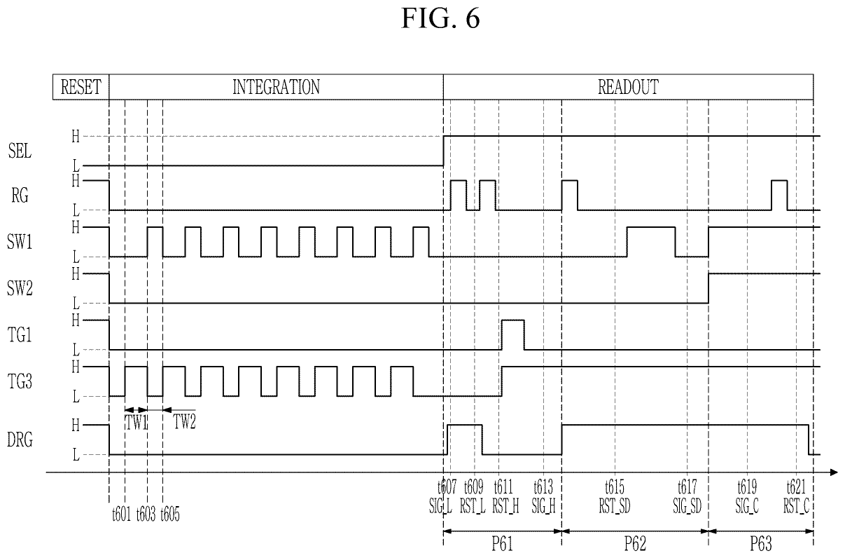

FIG. 6 is a timing diagram showing an operation of a pixel according to FIG. 5. FIG. 7 is a drawing showing a change of potential level in a pixel according to FIG. 5.

In FIG. 6, a scan period for driving the plurality of pixels PX on a row line basis may be shown. One scan period may sequentially include the reset period RESET, the integration period INTEGRATION, the readout period READOUT.

In the reset period RESET, charges stored in the first floating diffusion node FD1, the second floating diffusion node FD2, the third floating diffusion node FD3, and the fourth floating diffusion node FD4 may be reset.

In more detail, in the reset period RESET, the reset control signal RG, the first switch control signal SW1, the second switch control signal SW2, the first transmission control signal TG1, the third transmission control signal TG3, and the gain control signal DRG may all have the high-level H. Accordingly, the first floating diffusion node FD1, the second floating diffusion node FD2, the third floating diffusion node FD3, and the fourth floating diffusion node FD4 may all be reset to the power source voltage VDD.

The integration period INTEGRATION is a period in which the photoelectric element PD are exposed to light and thereby charges are generated. In the integration period INTEGRATION, the reset control signal RG, the first switch control signal SW1, the second switch control signal SW2, the first transmission control signal TG1, the third transmission control signal TG3, and the gain control signal DRG may transition from the high-level H to the low-level L. The first switch control signal SW1 and the third transmission control signal TG3 may toggle with a preset period.

In more detail, at t601, the third transmission control signal TG3 may transition from the low-level L to the high-level H. At t603, the third transmission control signal TG3 may transition from the high-level H to the low-level L, and the first switch control signal SW1 may transition from the low-level L to the high-level H. At t605, the third transmission control signal TG3 may transition from the low-level L to the high-level H, and the first switch control signal SW1 may transition from the high-level H to the low-level L. During the integration period INTEGRATION, a first state in which the first switch control signal SW1 is the low-level L and the third transmission control signal TG3 is the high-level H may be maintained during the first period TW1 (i.e., from t603 to t601), and a second state in which the first switch control signal SW1 is the high-level H and the third transmission control signal TG3 is the low-level L may be maintained during the second period TW2 (i.e., from t605 to t603).

At this time, the row driver 130 (refer to FIG. 1) may adjust the ratio of the first period TW1 and the second period TW2, such that a part of the charges generated by the photoelectric element PD may be controlled to be transferred to the storage diode SD. In an embodiment, the photo charges generated by the photoelectric element PD may be transferred to the storage diode SD at a ratio defined by Equation 1 below.

$$TW 2 / ( TW 1 + TW 2 ) \qquad ( Equation 1 )$$

For example, it is assumed that the ratio between the first period TW1 and the second period TW2 is 9:1. Assuming that the photoelectric element PD has generated ten photo charges, one of the photo charges may be transferred to the storage diode SD. That is, the row driver 130 (refer to FIG. 1) may adjust the ratio of the first period TW1 and the second period TW2, such that an effect similar to adjusting the sensitivity of the pixel 500 may be obtained.

As for the operation of the pixel 500 of the integration period INTEGRATION, FIG. 7 may be referred to. FIG. 7 illustrates the potential level of each element within the pixel 500 in the integration period INTEGRATION (refer to FIG. 6). The potential of each element is represented as the height in a D1 direction. In addition, the capacitance of each element is represented as the width in a D2 direction.

FIG. 7 represents potential levels of the first floating diffusion node FD1 and the second floating diffusion node FD2, the storage diode SD, a pixel voltage VDD, and the first capacitor C1 in the pixel 500. In addition, the first switch transistor SX1, the second switch transistor SX2, the third transmission transistor TX3, and the reset transistor RX region are shown.

The potential level of the channel region of the second switch transistor SX2 may vary between a first potential ON1 and a second potential OFF1 in response to the logical level of the second switch control signal SW2. The potential level of the channel region of the first switch transistor SX1 may vary between a first potential ON2 and a second potential OFF2 in response to the logical level of the first switch control signal SW1. The potential level of the channel region of the transmission transistor TX3 may vary between a first potential ON3 and a second potential OFF3 in response to the logical level of the third transmission control signal TG3. In addition, potential level of channel region of the reset transistor RX may vary between a first potential ON4 and a second potential OFF4 in response to the logical level of the reset control signal RG.

Although FIG. 7 illustrates that the first potential ON1, the first potential ON2, the first potential ON3, and the first potential ON4 are the same potential, and the second potential OFF1, the second potential OFF2, the second potential OFF3, and the second potential OFF4 are the same potential, the present disclosure is not limited thereto, and each of a plurality of first potentials may have a different value, and each of a plurality of second potentials may also have a different value.

Here, the photo charges generated by the photoelectric element PD may correspond to a total area of the hatched portions. The photoelectric element PD may generate photo charges at a level capable of exceeding the threshold voltage of the transmission transistor TX1. Photo charges exceeding the threshold voltage of the transmission transistor TX1 may cross the transmission transistor TX1 and move to another storage space through the second floating diffusion node FD2.

In more detail, when the first switch transistor SX1 is turned on according to the first switch control signal SW1, since the threshold voltage between the storage diode SD and the second floating diffusion node FD2 becomes low, charges having reached the second floating diffusion node FD2 may move to the storage diode SD.

When the third transmission transistor TX3 is turned on according to the third transmission control signal TG3, since the threshold voltage between the first floating diffusion node FD1 and the second floating diffusion node FD2 becomes low, charges having reached the second floating diffusion node FD2 may move to the first floating diffusion node FD1.

As shown in FIG. 6, the first switch transistor SX1 and the third transmission transistor TX3 may be alternately turned on. According to the first switch control signal SW1 and the third transmission control signal TG3, the charges having reached the second floating diffusion node FD2 may alternately move to the first switch transistor SX1 and the third transmission transistor TX3.

For example, assuming that the ratio between the first period TW1 and the second period TW2 is 9:1, the amount of charges transferred to the first floating diffusion node FD1 via the second floating diffusion node FD2 and the amount of charges transferred to the storage diode SD via the second floating diffusion node FD2 may be 9:1.

In summary, by controlling an operation of the first switch transistor SX1 and the third transmission transistor TX3, the charge generated by the photoelectric element PD may suitably move to the storage diode SD or the first floating diffusion node FD1 via the second floating diffusion node FD2.

Referring back to FIG. 6, the readout period READOUT is a period in which the pixel signal VOUT generated by the pixel 500 is transferred to the readout circuit 150 (refer to FIG. 1). One readout period READOUT may include a first period P61, a second period P62, and a third period P63. The first period P61 may be a period for performing an LCG operation and an HCG operation with respect to the photoelectric element PD. The second period P62 may be a period for performing a CDS operation with respect to the overflowed charged in the photoelectric element PD. The third period P63 may be a period for performing a readout operation with respect to charges overflowed from the photoelectric element PD and stored in the first capacitor C1. The charges stored in the first capacitor C1 may be readout by a digital double sampling (DDS) method or the like, instead of CDS.

In the readout period READOUT, the selection control signal SEL may transition from the low-level L to the high-level H. As the selection control signal SEL maintains the high-level H, the pixel 500 may read the pixel signal VOUT.

The gain control signal DRG may transition from the low-level L to the high-level H. According to the gain control signal DRG of the high-level H, the first floating diffusion node FD1 may be connected to the fifth floating diffusion node FD5, that is, the second capacitor C2. The pixel 500 may operate in the LCG mode.

At t607, image signal corresponding to the charges accumulated in the first floating diffusion node FD1 and the fifth floating diffusion node FD5 may be output through the column line CL. That is, at t607, the image signal SIG_L of the low conversion gain (LCG) mode with respect to the photoelectric element PD may be output as the pixel signal VOUT.

After t607, the reset control signal RG may transition from the low-level L to the high-level H. Meanwhile, the gain control signal DRG may maintain the high-level H. By the reset control signal RG of the high-level H and the gain control signal DRG of the high-level H, the charges accumulated in the first floating diffusion node FD1 and the fifth floating diffusion node FD5 may be reset to the power source voltage. Thereafter, the reset control signal RG may transition from the high-level H to the low-level L after a preset time.

At t609, a reset signal corresponding to the reset first floating diffusion node FD1 and the fifth floating diffusion node FD5 may be output through the column line CL. That is, at t609, the reset signal RST_L of the LCG mode with respect to the photoelectric element PD may be output as the pixel signal VOUT.

After t609, the gain control signal DRG may transition to the low-level L. Thereafter, the reset control signal RG may transition to the high-level H. According to the reset control signal RG of the high-level H, the first floating diffusion node FD1 may be reset. Thereafter, the reset control signal RG may be transitioned to the low-level L.

At t611, according to the gain control signal DRG of the low-level L, the fifth floating diffusion node FD5 is not connected to the first floating diffusion node FD1, and accordingly, the pixel 500 may operate in the high conversion gain (HCG) mode. A reset signal corresponding to the reset first floating diffusion node FD1 may be output through the column line CL. That is, at t611, the reset signal RST_H of the high conversion gain (HCG) mode with respect to the photoelectric element PD may be output as the pixel signal VOUT.

After the reset control signal RG transitions to the low-level L, the first transmission control signal TG1 and the third transmission control signal TG3 may transition to the high-level H. According to the third transmission control signal TG3 of the high-level H, the second floating diffusion node FD2 and the first floating diffusion node FD1 may be connected to each other. According to the first transmission control signal TG1 of the high-level H, the photo charges generated by the photoelectric element PD may be provided to the second floating diffusion node FD2 and the first floating diffusion node FD1. Thereafter, the first transmission control signal TG1 may transition to the low-level L.

At t613, an image signal corresponding to the first floating diffusion node FD1 may be output through the column line CL. That is, at t613, the image signal SIG_H of the high conversion gain (HCG) mode with respect to the photoelectric element PD may be output as the pixel signal VOUT.

After t613, the reset control signal RG and the gain control signal DRG may transition to the high-level H. At this time, the third transmission control signal TG3 may maintain the high-level H. According to the reset control signal RG of the high-level H, the first floating diffusion node FD1, the second floating diffusion node FD2, and the fifth floating diffusion node FD5 may be reset to the power source voltage. Thereafter, the reset control signal RG may transition to the low-level L.

At t615, a reset signal corresponding to the reset first floating diffusion node FD1, the second floating diffusion node FD2, and the fifth floating diffusion node FD5 may be output through the column line CL. That is, at t615, a reset signal RST_SD with respect to the photoelectric element PD may be output as the pixel signal VOUT.

After t615, the first switch control signal SW1 may transition to the high-level H. At this time, the third transmission control signal TG3 and the gain control signal DRG may maintain the high-level H. According to the first switch control signal SW1 of the high-level H, the third floating diffusion node FD3 and the second floating diffusion node FD2, the first floating diffusion node FD1, and the fifth floating diffusion node FD5 may be connected. The photo charges accumulated in the storage diode SD may be provided to the second floating diffusion node FD2, the first floating diffusion node FD1, and the fifth floating diffusion node FD5. Thereafter, the first switch control signal SW1 may transition to the low-level L.

At t617, an image signal corresponding to the first floating diffusion node FD1, the second floating diffusion node FD2, the third floating diffusion node FD3, and the fifth floating diffusion node FD5 may be output through the column line CL. That is, at t617, an image signal SIG_SD with respect to the storage diode SD may be output as the pixel signal VOUT.

After t617, the first switch control signal SW1, the second switch control signal SW2 may transition from the low-level L to the high-level H. At this time, the third transmission control signal TG3 and the gain control signal DRG may maintain the high-level H. According to the first switch control signal SW1 and the second switch control signal SW2 of the high-level H, the first floating diffusion node FD1, the second floating diffusion node FD2, the third floating diffusion node FD3, the fourth floating diffusion node FD4, and the fifth floating diffusion node FD5 may be connected to each other.

At t619, the image signal SIG_C corresponding to the charges accumulated in the first capacitor C1 may be output as the pixel signal VOUT.

After t619, the reset control signal RG may transition to the high-level H. At this time, the first switch control signal SW1, the second switch control signal SW2, the third transmission control signal TG3, and the gain control signal DRG may maintain the high-level H. According to the reset control signal RG of the high-level H, the first floating diffusion node FD1, the second floating diffusion node FD2, the third floating diffusion node FD3, the fourth floating diffusion node FD4, and the fifth floating diffusion node FD5 may be reset to the power source voltage. Thereafter, the reset control signal RG may transition to the low-level L.

At t621, a reset signal corresponding to the reset floating diffusion nodes FD1, FD2, FD3, FD4, and FD5 may be output through the column line CL. That is, at t621, the reset signal RST_C corresponding to the charges accumulated in the first capacitor C1 may be output as the pixel signal VOUT.

Meanwhile, in FIG. 6, although it is described that a plurality of transistors are enabled when a signal of the high-level H is applied, the present disclosure is not limited thereto, and an arbitrary transistor may be configured to be enabled when a signal of the low-level L is applied.

The image sensor including the pixel 500 may sense the image signal by using photo charges generated by a single photoelectric element PD. Specifically, in a low-illumination environment having a small amount of incident light, photo charges may be stored in one floating diffusion node (in FIG. 5, the first floating diffusion node FD1). In a high-illumination environment having a large amount of incident light, photo charges may be stored in a plurality of nodes (in FIG. 5, the first floating diffusion node FD1, the third floating diffusion node FD3, and the first capacitor C1), dividedly at preset ratios. Accordingly, since the image sensor including the pixel 500 may sense the mage signal even in a high-illuminance environment, a wide dynamic range may be secured. Furthermore, the image sensor including the pixel 500 may not cause optical problems such as discrepancy in relative illumination and color separation, which is due to inclusion of a plurality of photoelectric elements.

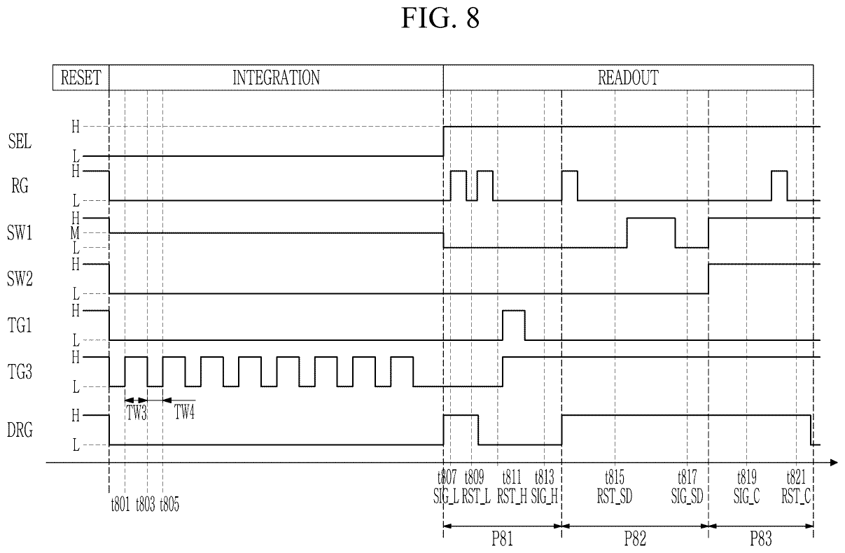

FIG. 8 is a still another timing diagram showing an operation of a pixel according to FIG. 5. FIG. 9 is a drawing showing a change of potential level in a pixel according to FIG. 5.

In FIG. 8, a scan period for driving the plurality of pixels PX on a row line basis may be shown. One scan period may sequentially include the reset period RESET, the integration period INTEGRATION, the readout period READOUT.

The description with respect to operations of the reset period RESET and the readout period READOUT of the pixel 500 described with reference to FIG. 6 may be applied to the reset period RESET and the readout period READOUT of FIG. 8.

Meanwhile, in the integration period INTEGRATION, the reset control signal RG, the second switch control signal SW2, the first transmission control signal TG1, the third transmission control signal TG3, and the gain control signal DRG may transition from the high-level H to the low-level L. The third transmission control signal TG3 may toggle with a preset period. The first switch control signal SW1 may transition to an intermediate level M between the high-level H and the low-level L.

In more detail, at t801, the third transmission control signal TG3 may transition from the low-level L to the high-level H. At T803, the third transmission control signal TG3 may transition from the high-level H to the low-level L. At T805, the third transmission control signal TG3 may transition from the low-level L to the high-level H. While the third transmission control signal TG3 is toggling, the first switch control signal SW1 may maintain the intermediate level M for maintaining an intermediate potential MID between the first potential ON2 for the first switch transistor SX1 to turn on the first switch transistor SX1 and the second potential OFF2 to turn off the first switch transistor SX1.

During the integration period INTEGRATION, the third transmission control signal TG3 may toggle with a preset period while maintaining the first period TW3 (i.e., from t803 to t801) and the second period TW4 (i.e., from t805 to t803).

At this time, the row driver 130 (refer to FIG. 1) may adjust the ratio of the first period TW3 and the second period TW4, such that a part of charges generated by the photoelectric element PD may be controlled to be transferred to the storage diode SD. In an embodiment, the photo charges generated by the photoelectric element PD may be transferred to the storage diode SD at a ratio defined by Equation 2 below.

$$TW 4 / ( TW 3 + TW 4 ) \qquad ( Equation 2 )$$

As for the operation of the pixel 500 of the integration period INTEGRATION, FIG. 9 may be referred to. FIG. 9 illustrates the potential level of each element within the pixel 500.

Among the first floating diffusion node FD1 and the second floating diffusion node FD2, the storage diode SD, the pixel voltage VDD, the potential level of the first capacitor C1, and the first switch transistor SX1, the second switch transistor SX2, the third transmission transistor TX3, and the reset transistor RX region of the pixel 500, description of portions redundant to the portions described with reference to FIG. 7 may be equally applied to FIG. 9 when not explicitly described otherwise.

The potential level of the channel region of the first switch transistor SX1 may vary between the first potential ON2 and the second potential OFF2 in response to the logical level of the first switch control signal SW1. For example, the first switch transistor SX1 may have the intermediate potential MID, corresponding to the logical level having the intermediate level M of the first switch control signal SW1.

The photo charges generated by the photoelectric element PD may correspond to an area of the hatched portion. The photoelectric element PD may generate photo charges at a level capable of exceeding the threshold voltage of the transmission transistor TX1. Photo charges exceeding the threshold voltage of the transmission transistor TX1 may cross the transmission transistor TX1 and move to another storage space through the second floating diffusion node FD2.

In more detail, the first switch transistor SX1 may maintain the intermediate potential MID according to the first switch control signal SW1. Accordingly, when the amount of charges having reached the second floating diffusion node FD2 exceeds the intermediate potential MID of the first switch transistor SX1, it may move to the storage diode SD.

When the third transmission transistor TX3 is turned on according to the third transmission control signal TG3, since the threshold voltage between the first floating diffusion node FD1 and the second floating diffusion node FD2 becomes low, charges having reached the second floating diffusion node FD2 may move to the first floating diffusion node FD1. However, even in this case, the amount of charges having reached the second floating diffusion node FD2 may be smaller than or equal to the intermediate potential MID of the first switch transistor SX1.

As shown in FIG. 8, while the first switch transistor SX1 maintains the intermediate potential MID according to the first switch control signal SW1, the third transmission transistor TX3 may repeat turning-on and turning-off. According to the control of the third transmission control signal TG3, the charges having reached the second floating diffusion node FD2 may alternately move to the first switch transistor SX1 and the third transmission transistor TX3. Meanwhile, the present disclosure is not limited thereto, and while the third transmission transistor TX3 maintains an intermediate potential, the first switch transistor SX1 may repeat turning-on and turning-off, such that movement of the charges having reached the second floating diffusion node FD2 may be controlled.

In summary, by controlling the third transmission transistor TX3 or the first switch operation of the transistor SX1, the charge generated by the photoelectric element PD may suitably move to the storage diode SD or the first floating diffusion node FD1 via the second floating diffusion node FD2.

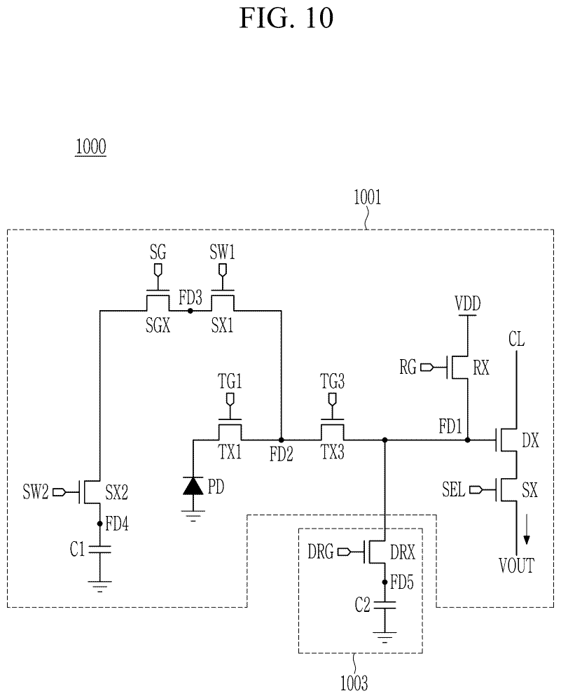

FIG. 10 is a circuit diagram of a pixel according to an embodiment of the present application.

In more detail, FIG. 10 is a circuit diagram of a pixel according to an embodiment of the present application that may be utilized as the pixel PX of FIG. 1. Referring to FIG. 10, a pixel 1000 may include a first circuit 1001 and a second circuit 1003. The first circuit 1001 may include the photoelectric element PD. The photoelectric element PD may variably generate photo charges depending on the intensity of light. The photo charges generated by the photoelectric element PD may be transmitted to and accumulated in at least one of the floating diffusion nodes FD1, FD2, FD3, FD4, and FD5. Although not shown in FIG. 10, in each of the floating diffusion nodes FD1, FD2, FD3, FD4, and FD5, a parasitic capacitor (not shown) may be formed, or an actual capacitor element may be connected thereto.

Among the description with respect to the first circuit 501 and the second circuit 503 described with reference to FIG. 5, description of portions redundant to the first circuit 1001 and the second circuit 1003 may be equally applied to the first circuit 1001 and the second circuit 1003 when not explicitly described otherwise.

Meanwhile, a storage gate transistor SGX may be located in the third floating diffusion node FD3. The storage gate transistor SGX may be a charge storage element capable of storing the photo charges generated by the photoelectric element PD before transferring it to the fourth floating diffusion node FD4. The storage gate transistor SGX may be controlled by a storage gate signal SG. In an embodiment, the amount of charges that may be stored in the storage gate transistor SGX based on the storage gate signal SG may vary. The storage gate transistor SGX may be implemented in a structure in which storage diodes are additionally formed within the semiconductor substrate below the storage gate transistor SGX.

The storage gate transistor SGX may be implemented in the form of a MOS transistor within the semiconductor substrate. The storage gate transistor SGX may apply the storage gate signal SG to the gate and store photo charges in the body portion of the storage gate transistor SGX. The amount of charges that may be stored in the storage gate transistor SGX may be different according to the magnitude of the applied storage gate signal SG. However, since the storage gate transistor SGX stores the charges in the body portion through the storage gate signal SG, the magnitude of the dark current that may be generated while reading the pixel signal is large, and the amount of charges remaining in the storage gate transistor SGX when resetting to the power source voltage may be large.

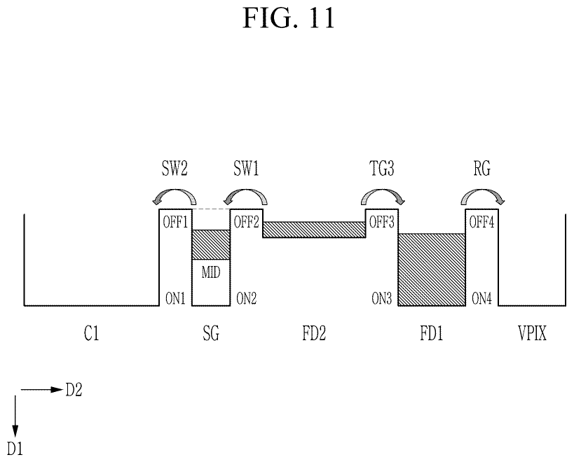

FIG. 11 is a drawing showing a change of potential level in a pixel according to FIG. 10.

In more detail, potential levels of respective elements in the pixel 1000 in the integration period when the pixel 1000 operates according to the timing diagrams according to FIG. 6 or FIG. 8 are shown.

Among the description of the first floating diffusion node FD1 and the second floating diffusion node FD2, the pixel voltage VDD, the potential level of the first capacitor C1, and the first switch transistor SX1, the second switch transistor SX2, the third transmission transistor TX3, and the reset transistor RX region of the pixel 1000, description of portions redundant to the portions described with reference to FIG. 7 may be equally applied to FIG. 11 when not explicitly described otherwise.

The photo charges generated by the photoelectric element PD may correspond to a total area of the hatched portions. The photoelectric element PD may generate photo charges at a level capable of exceeding the threshold voltage of the transmission transistor TX1. Photo charges exceeding the threshold voltage of the transmission transistor TX1 may cross the transmission transistor TX1 and move to the second floating diffusion node FD2.

The potential level of the storage gate transistor SGX may vary according to the level of the storage gate signal SG. For example, FIG. 11 illustrates the case where the storage gate signal SG has an intermediate level and the storage gate transistor SGX has the intermediate potential MID.

Meanwhile, when the storage gate signal SG has a higher level than the intermediate level, the storage gate transistor SGX may store a greater amount of charges. The controller 110 may set the level of the storage gate signal SG applied to the storage gate transistor SGX by the row driver 130 (refer to FIG. 1) based on the level of photo charges generated by the photoelectric element PD within the pixel 1000.

When the first switch transistor SX1 is turned on according to the first switch control signal SW1, since the threshold voltage between the storage gate transistor SGX and the second floating diffusion node FD2 becomes low, charges having reached the second floating diffusion node FD2 may move to the storage gate transistor SGX.

When the third transmission transistor TX3 is turned on according to the third transmission control signal TG3, since the threshold voltage between the first floating diffusion node FD1 and the second floating diffusion node FD2 becomes low, charges having reached the second floating diffusion node FD2 may move to the first floating diffusion node FD1.

In summary, by controlling the operation of the first switch transistor SX1 and the third transmission transistor TX3, the charge generated by the photoelectric element PD may suitably move to the storage gate transistor SGX or the first floating diffusion node FD1 via the second floating diffusion node FD2.

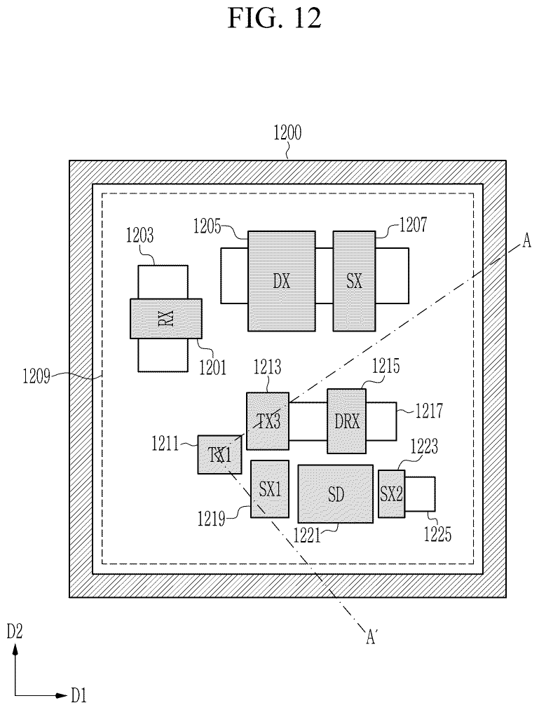

FIG. 12 is a schematic top view of a layout of a pixel according to FIG. 5.

In more detail, FIG. 12 represents the arrangement of respective elements included in the pixel 500 of FIG. 5 according to an example embodiment.

As shown in FIG. 12, a pixel may include a reset transistor (RX) region 1201, a power source voltage region 1203, a driving transistor (DX) region 1205, a selection transistor (SX) region 1207, a photoelectric element (PD) region 1209, a first transmission transistor (TX1) region 1211, a third transmission transistor (TX3) region 1213, a gain control transistor (DRX) region 1215, a second capacitor region 1217, a first switch transistor (SX1) region 1219, a storage diode (SD) region 1221, a second switch transistor (SX2) region 1223, a first capacitor region 1225.

In an embodiment, in order to prevent electrical and optical crosstalk phenomena between adjacent pixels, a boundary portion 1200 of the pixel may be formed by a deep trench isolation (DTI) process. For example, the pixel may be formed on a substrate including an oxide or the like, and the substrate may include a highly reflective material, for example, polysilicon including boron. When the substrate includes polysilicon including boron, the substrate may be provided as a p-well region with respect to a plurality of transistors RX, DX, SX, TX1, TX3, DRX, SX1, and SX2. A partial region of the p-well region may be implanted with n-type impurities, so as to be provided as drain and source regions of each of the transistors RX, DX, SX, TX1, TX3, DRX, SX1, and SX2. Among the p-well region, a partial region provided as the drain and source region may be doped with n+. Accordingly, the photo charges generated in a photoelectric element region 1209 may move to at least one of the first capacitor region 1225, the second capacitor region 1217, plurality of floating diffusion region (not shown), and a storage diode region 1221.

The reset transistor region 1201, the driving transistor (DX) region 1205, the selection transistor (SX) region 1207, the first transmission transistor (TX1) region 1211, the third transmission transistor (TX3) region 1213, the gain control transistor region 1215, the first switch transistor (SX1) region 1219, and the second switch transistor (SX2) region 1223 may be formed in a vertical gate structure extending from the first surface, which is defined as an upper surface of the pixel, in a depth direction, that is, may extend in the depth direction perpendicular to the upper surface of the pixel.

When the reset control signal RG is applied to a reset gate electrode located in an upper portion of the reset transistor region 1201 and a transfer path of the charges is formed in a lower portion of the reset gate electrode, the floating diffusion region FD1 (refer to FIG. 5) and the power source voltage region 1203 are connected, such that the charge accumulated in the floating diffusion region may be transferred to the power source voltage region 1203.

The power source voltage region 1203 may be a conductive region to which the power source voltage is supplied.

In the driving transistor (DX) region 1205, the signal generated by the charges accumulated in the floating diffusion region FD1 (refer to FIG. 5) may be output to the wire connected to the driving transistor region 1205.

Meanwhile, when the reset transistor region 1201, the driving transistor (DX) region 1205, the selection transistor (SX) region 1207, the first transmission transistor (TX1) region 1211, the third transmission transistor (TX3) region 1213, the gain control transistor region 1215, the first switch transistor (SX1) region 1219, and the second switch transistor (SX2) region 1223 are formed in the vertical gate structure, the photoelectric element region 1209 may be located over the entire region of the pixel. The photoelectric element may be located in a lower portion of the photoelectric element region 1209, and in the photoelectric element region 1209, photo charges may be generated based on the incident light. Meanwhile, the photoelectric element region 1209 is not limited to the region shown in FIG. 12, and may be located in a suitable region within the pixel.

The storage diode region 1221, the first capacitor region 1225, and the second capacitor region 1217 may be regions for storing charges.

A first transmission transistor region 1211 may be adjacent to the photoelectric element disposed in the lower portion of the first transmission transistor region 1211.

A third transmission transistor region 1213 and a first switch transistor region 1219 may be located to partially overlap in the first direction D1. In an embodiment, the third transmission transistor region 1213 and the first switch transistor region 1219 may be disposed apart from the first transmission transistor region 1211 in the first direction D1.

The third transmission transistor region 1213 may be located to be apart from the first switch transistor region 1219 in the second direction D2. Meanwhile, the present disclosure is not limited thereto, and the first switch transistor region 1219 may be located to be apart from the third transmission transistor region 1213 in the second direction D2.

In an embodiment, the storage diode region 1221 may be disposed apart from the first switch transistor region 1219 in the first direction D1. The storage diode region 1221 may be disposed through a DTI process. Accordingly, the storage diode region 1221 may be disposed to be separate from the first switch transistor region 1219.

A second switch transistor region 1223 may be disposed apart from the storage diode region 1221 in the first direction D1. In addition, the first capacitor region 1225 may be disposed to be adjacent to the second switch transistor region 1223 in the first direction D1.

The first transmission control signal may be applied to a first transmission gate electrode located in an upper portion of the first transmission transistor region 1211 such that a transfer path of the photo charges generated by the photoelectric element region 1209 may be located in the lower portion of the first transmission gate electrode. In an embodiment, when the first switch control signal SW1 of an enable level is applied to an electrode of the first switch transistor region 1219, photo charges may be transferred in the storage diode region 1221 via the first switch transistor region 1219. Thereafter, when the second switch control signal SW2 of an enable level is applied to an electrode of the second switch transistor region 1223, the photo charges transferred to the storage diode region 1221 may be transferred to the first capacitor region 1225. In another embodiment, when the third transmission control signal TG3 of an enable level is applied to an electrode of a third transistor region 1213, photo charges may be transferred in floating diffusion region (not shown) via the third transmission transistor region 1213. Thereafter, when the gain control signal DRG is applied to an electrode of the gain control transistor region 1215, the photo charges transferred to the floating diffusion region may be transferred to the second capacitor region 1217.

Meanwhile, although FIG. 12 illustrates that the pixel includes the storage diode region 1221, the present disclosure is not limited thereto, and instead, a storage gate region may be located in the storage diode region 1221.

FIG. 13 is a cross-sectional view showing an image sensor taken along line A-A′ of FIG. 12.

In more detail, an image sensor 1300 may include a first substrate 1310, the photoelectric element PD, an isolation layer 1315, a surface insulation layer 1350, a grid pattern 1360, a first protective layer 1365, a color filter 1370, microlens 1381 and a second protective layer 1385.

The first substrate 1310 may include the first surface 1310a and the second surface 1310b that are opposite to each other. In an embodiment, the first surface 1310a may be referred to as a front side of the first substrate 1310, and the second surface 1310b may be referred to as a back side of the first substrate 1310. In an embodiment, the second surface 1310b of the first substrate 1310 may be a light receiving surface on which the light is incident. That is, an image sensor according to an embodiment may be a back side illuminated (BSI) image sensor.

The first substrate 1310 may be a semiconductor substrate. For example, the first substrate 1310 may be bulk silicon or silicon-on-insulator (SOI). Alternatively, the first substrate 1310 may include a base substrate on which an epitaxial layer is formed.

In an embodiment, the first substrate 1310 may have a first conductivity type. For example, the first substrate 1310 may include p-type impurities (e.g., boron (B)). In an embodiment, the first conductivity type is assumed to be p-type, but the present disclosure is not limited thereto, and the first conductivity type may be n-type.

The pixel PX13 may be located on the first substrate 1310. The photoelectric element PD may be located within the first substrate 1310 of the pixel PX13. The photoelectric element PD may have the first conductivity type. In an embodiment, the first conductivity type is assumed to be n-type, but the present disclosure is not limited thereto, and the first conductivity type may be p-type. The photoelectric element PD may be formed, for example, by ion-implantation of n-type impurities (e.g., phosphorus (P) or arsenic (As)) into the p-type first substrate 1310.

In an embodiment, the photoelectric element PD may have a potential gradient in a direction (e.g., vertical direction) crossing the first surface 1310a and the second surface 1310b of the first substrate 1310. For example, impurity concentration of the photoelectric element PD may decrease from the first surface 1310a toward the second surface 1310b.

A second floating diffusion region FD2 may be located within the first substrate 1310 of the pixel PX13. The second floating diffusion region FD2 may be located within the first substrate 1310 of the pixel PX13. The second floating diffusion region FD2 may have a second conductivity type. For example, the second floating diffusion region FD2 may be located within the p-type first substrate 1310 by being ion-implanted with n-type impurities. The second floating diffusion region FD2 may act as a charge moving path. Accordingly, the second floating diffusion region FD2 may have a low doping concentration or may be in the intrinsic state, and preferably, may be formed to have a small area.

In an embodiment, the first transmission transistor TX1, the third transmission transistor TX3, the first switch transistor SX1 may be formed to be close to each other, such that the second floating diffusion region FD2 may be omitted practically.

The first transmission transistor TX1 may be located on the first surface 1310a of the first substrate 1310. The first transmission transistor TX1 may include a first transfer gate PTG1, a first gate insulating layer, and a first gate spacer. The first gate insulating layer may be disposed between the first transfer gate PTG1 and the first substrate 1310, and the first gate spacer may be disposed on both side walls of the first transfer gate PTG1.

In an embodiment, the first transfer gate PTG1 may be a vertical transfer gate. That is, at least a portion of the gate of the first transfer gate PTG1 may be buried within the first substrate 1310. For example, a trench extending from the first surface 1300a of the first substrate 1310 may be located within the first substrate 1310. At least a portion of the gate of the first transfer gate PTG1 may be located to fill the trench. Accordingly, a lower surface of the first transfer gate PTG1 may be disposed within the first substrate 1310. In an embodiment, the width of the first transfer gate PTG1 may decrease as the height of the first transfer gate PTG1 increases in a direction away from the first surface 1310a of the first substrate 1310. This may be due to the characteristics of the etching process for forming the trench.

The third transmission transistor TX3 may be located on the first surface 1310a of the first substrate 1310. The third transmission transistor TX3 may include a gate and a first gate insulating layer 1331. The first gate insulating layer 1331 may be disposed between the gate and the first substrate 1310.

The first switch transistor SX1 may be located on the first surface 1310a of the first substrate 1310. The first switch transistor SX1 may include a gate and a second gate insulating layer 1333. The second gate insulating layer 1333 may be disposed between the gate and the first substrate 1310.

A first line insulation layer 1330 may include, for example, at least one of low dielectric constant (low-k) materials having a lower dielectric constant than silicon oxide, silicon nitride, silicon oxynitride and silicon oxide, but is not limited thereto.

The isolation layer 1315 may be located within the first substrate 1310. The isolation layer 1315 may be disposed, for example, by burying an insulating material within a shallow trench formed by patterning the first substrate 1310. The isolation layer 1315 may be adjacent to the first surface 1310a of the first substrate 1310, and may extend from the first surface 1310a.

The isolation layer 1315 may overlap a pixel separation pattern 1340. A portion of the pixel separation pattern 1340 may be located within the isolation layer 1315. The pixel separation pattern 1340 may penetrate the isolation layer 1315. The isolation layer 1315 may include an insulating material.

The surface insulation layer 1350 may be located on the first surface 1310a of the first substrate 1310. The surface insulation layer 1350 may cover the first surface 1310a of the first substrate 1310. The surface insulation layer 1350 may include a insulating material.

The surface insulation layer 1350 may function as an anti-reflection layer, and thereby prevent reflection of light incident on the first substrate 1310, such that the light reception rate of a photoelectric element PD may be improved. In addition, the surface insulation layer 1350 may function as an planarization layer, and thereby the color filter 1370 and microlens 1381 may be formed in a uniform height.

The color filter 1370 may be located on the surface insulation layer 1350. In an embodiment, the grid pattern 1360 may be located between color filter 1370. The grid pattern 1360 may be located on the surface insulation layer 1350. The grid pattern 1360 may be formed in a lattice pattern in the plan view, and may be interposed between the color filter 1370.

In an embodiment, the grid pattern 1360 may include a conductive pattern 1361 and a low refractive index pattern 1363. The conductive pattern 1361 and the low refractive index pattern 1363 may be sequentially stacked, for example, on the surface insulation layer 1350. The conductive pattern 1361 may include a conductive material. The low refractive index pattern 1363 may include a low refractive index material having a lower refractive index than silicon (Si). The low refractive index pattern 1363 may improve light collection efficiency by refracting or reflecting obliquely incident light, thereby improving the quality of the image sensor.

In an embodiment, the first protective layer 1365 may be located on the surface insulation layer 1350 and the grid pattern 1360.

The first protective layer 1365 may include, for example, aluminum oxide, but is not limited thereto. The first protective layer 1365 may prevent damage of the surface insulation layer 1350 and the grid pattern 1360.

The microlens 1381 may be located on the color filter 1370. The microlens 1381 may have a convex shape, and may have a predetermined radius of curvature. Accordingly, the microlens 1381 may collect light incident on the photoelectric element PD. The microlens 1381 may include, for example, a light-transmissive resin, but is not limited thereto.

In an embodiment, the second protective layer 1385 may be located on the microlens 1381. The second protective layer 1385 may extend along a surface of the microlens 1381. The second protective layer 1385 may include, for example, inorganic material oxide layer. For example, the second protective layer 1385 may include at least one of silicon oxide, titanium oxide, zirconium oxide, hafnium oxide, and a combination thereof, but is not limited thereto. In some embodiments, the second protective layer 1385 may include low temperature oxide (LTO).

The second protective layer 1385 may protect the microlens 1381 from the outside. For example, the second protective layer 1385 may include an inorganic material oxide layer, so as to protect the microlens 1381 including that organic material. In addition, the second protective layer 1385 may improve the quality of the image sensor by improving light collection efficiency of the microlens 1381. For example, the second protective layer 1385 may decrease reflection, refraction, scattering, etc. of incident light reaching the space between the microlenses 1381, by filling the space between the microlenses 1380.

Meanwhile, the number and arrangement of layers of wires and contacts shown in FIG. 13 are merely an example, and the present disclosure is not limited thereto.

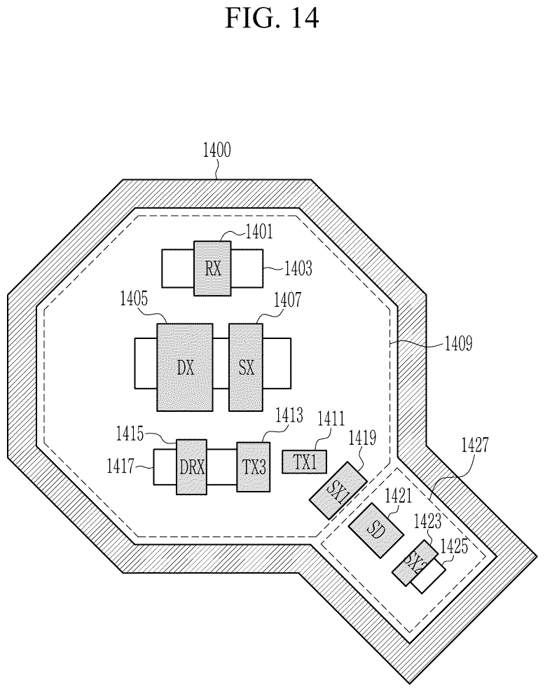

FIG. 14 is a schematic top view of a layout of a pixel according to FIG. 5.

In more detail, FIG. 14 represents the arrangement of respective elements included in the pixel 500 of FIG. 5 according to an example embodiment.

As shown in FIG. 14, a pixel may include a reset transistor (RX) region 1401, a power source voltage region 1403, a driving transistor (DX) region 1405, a selection transistor (SX) region 1407, a photoelectric element (PD) region 1409, a first transmission transistor (TX1) region 1411, a third transmission transistor (TX3) region 1413, a gain control transistor region 1415, a second capacitor region 1417, a first switch transistor (SX1) region 1419, storage diode (SD) region 1421, a second switch transistor (SX2) region 1423, a first capacitor region 1425.

In an embodiment, in order to prevent electrical and optical crosstalk phenomena between adjacent pixels, a boundary portion 1400 of the pixel may be formed by a DTI process. For example, the pixel may be located on a substrate including an oxide or the like, and the substrate may include a highly reflective material, for example, polysilicon including boron. When the substrate includes polysilicon including boron, the substrate may be provided as a p-well region with respect to the plurality of transistors RX, DX, SX, TX1, TX3, DRX, SX1, and SX2. A partial region of the p-well region may be implanted with n-type impurities, so as to be provided as drain and source regions of each of the transistors RX, DX, SX, TX1, TX3, DRX, SX1, and SX2. Among the p-well region, a partial region provided as the drain and source region may be doped with n+. Accordingly, the photo charges generated in a photoelectric element region 1409 may move to at least one of the first capacitor region 1425, the second capacitor region 1417, plurality of floating diffusion region (not shown), and a storage diode region 1421.

The reset transistor region 1401, the driving transistor (DX) region 1405, the selection transistor (SX) region 1407, the first transmission transistor (TX1) region 1411, the third transmission transistor (TX3) region 1413, the gain control transistor region 1415, the first switch transistor (SX1) region 1419, and the second switch transistor (SX2) region 1423 may be formed in a vertical gate structure extending from the first surface, which is defined as an upper surface of the pixel, in a depth direction, that is, may extend in the depth direction perpendicular to the upper surface of the pixel.

When the reset control signal RG is applied to a reset gate electrode located in an upper portion of the reset transistor region 1401 and a transfer path of the charges is formed in a lower portion of the reset gate electrode, the floating diffusion region FD1 (refer to FIG. 5) and the power source voltage region 1403 are connected, such that the charges accumulated in the floating diffusion region may be transferred to the power source voltage region 1403.

The power source voltage region 1403 may be a conductive region to which the power source voltage is supplied.

In the driving transistor region (DX) 1405, the signal generated by the charges accumulated in the floating diffusion region FD1 (refer to FIG. 5) may be output to the wire connected to the driving transistor region 1405.

Meanwhile, when the reset transistor region 1401, the driving transistor (DX) region 1405, the selection transistor (SX) region 1407, the first transmission transistor (TX1) region 1411, the third transmission transistor (TX3) region 1413, the gain control transistor region 1415, the first switch transistor (SX1) region 1419, and the second switch transistor (SX2) region 1423 are formed in the vertical gate structure, the photoelectric element region 1409 may be located over a partial region of the pixel. The photoelectric element may be located in a lower portion of the photoelectric element region 1409, and in the photoelectric element region 1409, photo charges may be generated based on the incident light. Meanwhile, the photoelectric element region 1409 is not limited to the region shown in FIG. 14, and may be located in a suitable region within the pixel.

The storage diode region 1421, the first capacitor region 1425, and the second capacitor region 1417 may be regions for storing charges.

A first transmission transistor region 1411 may be adjacent to the photoelectric element disposed in the lower portion.

A third transmission transistor region 1413 may be disposed on a first side of the first transmission transistor region 1411, and a first switch transistor region 1419 may be disposed on a second side of the first transmission transistor region 1411.

In an embodiment, the storage diode region 1421 may be disposed to be apart from the first switch transistor region 1419. The storage diode region 1421 may be disposed through a DTI process. Accordingly, the storage diode region 1421 may be disposed to be separate from the first switch transistor region 1419.

A second switch transistor region 1423 may be disposed to be apart from the storage diode region 1421. In addition, the first capacitor region 1425 may be disposed to be adjacent to the second switch transistor region 1423.

The first transmission control signal may be applied to a first transmission gate electrode located in an upper portion of the first transmission transistor region 1411 such that a transfer path of the photo charges generated by the photoelectric element region 1409 may be located in the lower portion of the first transmission gate electrode. In an embodiment, when the first switch control signal SW1 of an enable level is applied to an electrode of the first switch transistor region 1419, photo charges may be transferred in the storage diode region 1421 via the first switch transistor region 1419. Thereafter, when the second switch control signal SW2 of an enable level is applied to an electrode of the second switch transistor region 1423, the photo charges transferred to the storage diode region 1421 may be transferred to the first capacitor region 1425. In another embodiment, when the third transmission control signal TG3 of an enable level is applied to an electrode of a third transistor region 1413, photo charges may be transferred to a floating diffusion region (not shown) via the third transmission transistor region 1413. Thereafter, when the gain control signal DRG is applied to an electrode of the gain control transistor region 1415, the photo charges transferred to the floating diffusion region may be transferred to the second capacitor region 1417.

As shown in FIG. 14, the storage diode region 1421, the second switch transistor region 1423, and a light blocking layer 1427 may be located on the first capacitor region 1425. In an embodiment, the light blocking layer 1427 may be disposed on the second surface 1310b of the first substrate 1310. The light blocking layer 1427 may include at least one metal material of, for example, tungsten, aluminum, titanium, ruthenium, cobalt, nickel, copper, gold, silver, or platinum. In this regard, referring to FIG. 13 together, the light blocking layer 1427 may be located at the same level as the conductive pattern 1361. Accordingly, the light leakage phenomenon, in which light leaks through an edge of the pixel and may be incident on the storage diode region 1421 and the first capacitor region 1425, may be prevented.

Meanwhile, although FIG. 14 illustrates that the pixel includes the storage diode region 1421, the present disclosure is not limited thereto, and instead, a storage gate region may be located in the storage diode region 1421.

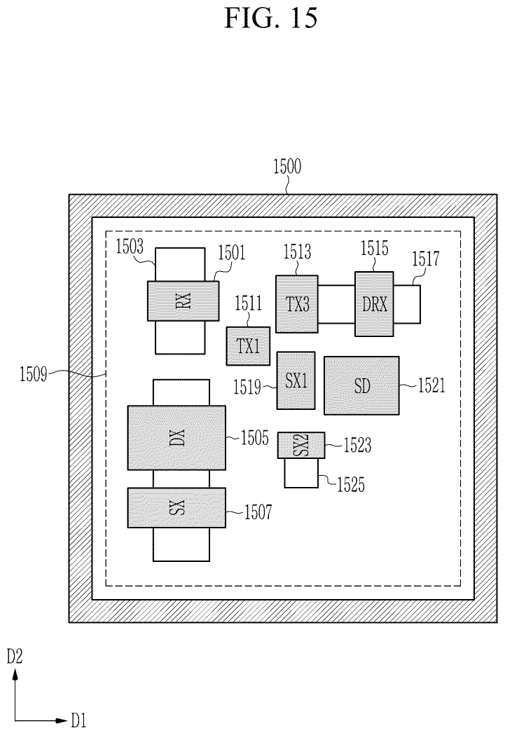

FIG. 15 is a schematic top view of a layout of a pixel according to FIG. 5.

In more detail, FIG. 15 represents the arrangement of respective elements included in the pixel 500 of FIG. 5 according to an example embodiment.

As shown in FIG. 15, a pixel may include a reset transistor (RX) region 1501, a power source voltage region 1503, a driving transistor (DX) region 1505, a selection transistor (SX) region 1507, a photoelectric element (PD) region 1509, a first transmission transistor (TX1) region 1511, a third transmission transistor (TX3) region 1513, a gain control transistor region (DRX) 1515, a second capacitor region 1517, a first switch transistor (SX1) region 1519, a storage diode (SD) region 1521, a second switch transistor (SX2) region 1523, a first capacitor region 1525.

In an embodiment, in order to prevent electrical and optical crosstalk phenomena between adjacent pixels, a boundary portion 1500 of the pixel may be formed by a DTI process. For example, the pixel may be located on a substrate including an oxide or the like, and the substrate may include a highly reflective material, for example, polysilicon including boron. When the substrate includes polysilicon including boron, the substrate may be provided as the p-well region with respect to the plurality of transistors RX, DX, SX, TX1, TX3, DRX, SX1, and SX2. A partial region of the p-well region may be implanted with n-type impurities, so as to be provided as drain and source regions of each of the transistors RX, DX, SX, TX1, TX3, DRX, SX1, and SX2. Among the p-well region, a partial region provided as the drain and source region may be doped with n+. Accordingly, the photo charges generated in a photoelectric element region 1509 may move to at least one of the first capacitor region 1525, the second capacitor region 1517, plurality of floating diffusion region (not shown), and a storage diode region 1521.

The reset transistor region 1501, the driving transistor (DX) region 1505, the selection transistor (SX) region 1507, the first transmission transistor (TX1) region 1511, the third transmission transistor (TX3) region 1513, a gain control transistor region 1515, the first switch transistor (SX1) region 1519, and the second switch transistor (SX2) region 1523 may be formed in a vertical gate structure extending from the first surface, which is defined as an upper surface of the pixel, in a depth direction, that is, may extend in the depth direction perpendicular to the upper surface of the pixel.

When the reset control signal RG is applied to a reset gate electrode located in an upper portion of the reset transistor region 1501 and a transfer path of the charges is formed in a lower portion of the reset gate electrode, the floating diffusion region FD1 (refer to FIG. 5) and the power source voltage region 1503 are connected, such that the charges accumulated in the floating diffusion region may be transferred to the power source voltage region 1503.

The power source voltage region 1503 may be a conductive region to which the power source voltage is supplied.

In a driving transistor region 1505, the signal generated by the charges accumulated in the floating diffusion region FD1 (refer to FIG. 5) may be output to the wire connected to the driving transistor region 1505.

Meanwhile, when the reset transistor region 1501, the driving transistor (DX) region 1505, the selection transistor (SX) region 1507, the first transmission transistor (TX1) region 1511, the third transmission transistor (TX3) region 1513, the gain control transistor region 1515, the first switch transistor (SX1) region 1519, and the second switch transistor (SX2) region 1523 are formed in the vertical gate structure, the photoelectric element region 1509 may be located over the entire region of the pixel. The photoelectric element may be located in a lower portion of the photoelectric element region 1509, and in the photoelectric element region 1509, photo charges may be generated based on the incident light. Meanwhile, the photoelectric element region 1509 is not limited to the region shown in FIG. 15, and may be located in a suitable region within the pixel.

The storage diode region 1521, the first capacitor region 1525, and the second capacitor region 1517 may be regions for storing charges.

A first transmission transistor region 1511 may be adjacent to the photoelectric element disposed in the lower portion.

A third transmission transistor region 1513 and a first switch transistor region 1519 may be located to partially overlap in the first direction D1. In an embodiment, the third transmission transistor region 1513 and the first switch transistor region 1519 may be disposed apart from the first transmission transistor region 1511 in the first direction D1.

The third transmission transistor region 1513 may be located to be apart from the first switch transistor region 1519 in the second direction D2. Meanwhile, the present disclosure is not limited thereto, and the first switch transistor region 1519 may be located to be apart from the third transmission transistor region 1513 in the second direction D2.

In an embodiment, the storage diode region 1521 may be disposed apart from the first switch transistor region 1519 in the first direction D1. The storage diode region 1521 may be disposed through a DTI process. Accordingly, the storage diode region 1521 may be disposed to be separate from the first switch transistor region 1519.

A second switch transistor region 1523 may be disposed apart from the storage diode region 1521 in the second direction D2. In addition, the first capacitor region 1525 may be disposed to be adjacent to the second switch transistor region 1523 in the second direction D2.

The first transmission control signal may be applied to a first transmission gate electrode located in an upper portion of the first transmission transistor region 1511 such that a transfer path of the photo charges generated by the photoelectric element region 1509 may be located in the lower portion of the first transmission gate electrode. In an embodiment, when the first switch control signal SW1 of an enable level is applied to an electrode of the first switch transistor region 1519, photo charges may be transferred in the storage diode region 1521 via the first switch transistor region 1519. Meanwhile, when the second switch control signal SW2 of an enable level is applied to an electrode of the second switch transistor region 1523, photo charges may be transferred from the first switch transistor region 1519 to the first capacitor region 1525 via the second switch transistor region 1523, without being transferred to the storage diode region 1521. Accordingly, the storage diode region 1521 of a larger area may be secured.

In a still another embodiment, when the third transmission control signal TG3 of an enable level is applied to an electrode of a third transistor region 1513, photo charges may be transferred to a floating diffusion region (not shown) via the third transmission transistor region 1513. Thereafter, when the gain control signal DRG is applied to an electrode of the gain control transistor region 1515, the photo charges transferred to the floating diffusion region may be transferred to the second capacitor region 1517.

Meanwhile, although FIG. 15 illustrates that the pixel includes the storage diode region 1521, the present disclosure is not limited thereto, and instead, a storage gate region may be located in the storage diode region 1521.

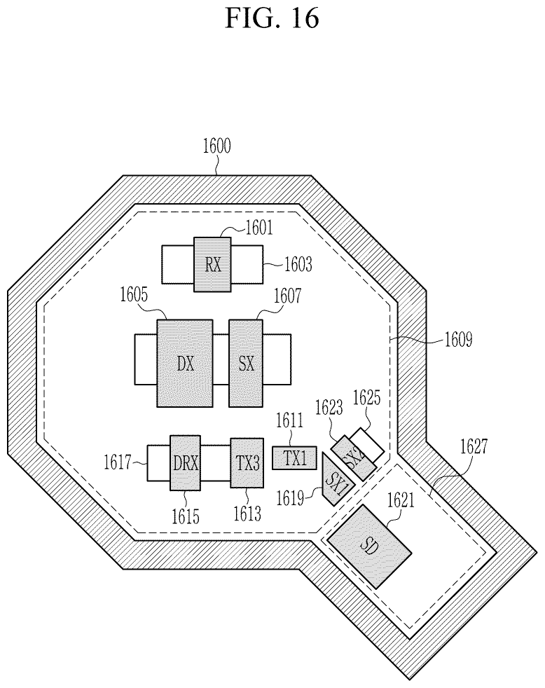

FIG. 16 is a schematic top view of a layout of a pixel according to FIG. 5.

In more detail, FIG. 16 represents the arrangement of respective elements included in the pixel 500 of FIG. 5 according to an example embodiment.

As shown in FIG. 16, a pixel may include a reset transistor (RX) region 1601, a power source voltage region 1603, a driving transistor (DX) region 1605, a selection transistor (SX) region 1607, a photoelectric element (PD) region 1609, a first transmission transistor (TX1) region 1611, a third transmission transistor (TX3) region 1613, a gain control transistor region 1615, a second capacitor region 1617, a first switch transistor (SX1) region 1619, a storage diode (SD) region 1621, a second switch transistor (SX2) region 1623, a first capacitor region 1625.

In an embodiment, in order to prevent electrical and optical crosstalk phenomena between adjacent pixels, a boundary portion 1600 of the pixel may be formed by a DTI process. For example, the pixel may be located on a substrate including an oxide or the like, and the substrate may include a highly reflective material, for example, polysilicon including boron. When the substrate includes polysilicon including boron, the substrate may be provided as the p-well region with respect to the plurality of transistors RX, DX, SX, TX1, TX3, DRX, SX1, and SX2. A partial region of the p-well region may be implanted with n-type impurities, so as to be provided as drain and source regions of each of the transistors RX, DX, SX, TX1, TX3, DRX, SX1, and SX2. Among the p-well region, a partial region provided as the drain and source region may be doped with n+. Accordingly, the photo charges generated in a photoelectric element region 1609 may move to at least one of the first capacitor region 1625, the second capacitor region 1617, plurality of floating diffusion region (not shown), and a storage diode region 1621.

The reset transistor region 1601, the driving transistor (DX) region 1605, the selection transistor (SX) region 1607, the first transmission transistor (TX1) region 1611, the third transmission transistor (TX3) region 1613, the gain control transistor region 1615, the first switch transistor (SX1) region 1619, and the second switch transistor (SX2) region 1623 may be formed in a vertical gate structure extending from the first surface, which is defined as an upper surface of the pixel, in a depth direction, that is, may extend in the depth direction perpendicular to the upper surface of the pixel.

When the reset control signal RG is applied to a reset gate electrode located in an upper portion of the reset transistor region 1601 and a transfer path of the charges is formed in a lower portion of the reset gate electrode, the floating diffusion region FD1 (refer to FIG. 5) and the power source voltage region 1603 are connected, such that the charges accumulated in the floating diffusion region may be transferred to the power source voltage region 1603.

The power source voltage region 1603 may be a conductive region to which the power source voltage is supplied.

In a driving transistor region 1605, the signal generated by the charges accumulated in the floating diffusion region FD1 (refer to FIG. 5) may be output to the wire connected to the driving transistor region 1605.

Meanwhile, when the reset transistor region 1601, the driving transistor (DX) region 1605, the selection transistor (SX) region 1607, the first transmission transistor (TX1) region 1611, the third transmission transistor (TX3) region 1613, the gain control transistor region 1615, the first switch transistor (SX1) region 1619, and the second switch transistor (SX2) region 1623 are formed in the vertical gate structure, the photoelectric element region 1609 may be located over a partial region of the pixel. The photoelectric element may be located in a lower portion of the photoelectric element region 1609, and in the photoelectric element region 1609, photo charges may be generated based on the incident light. Meanwhile, the photoelectric element region 1609 is not limited to the region shown in FIG. 16, and may be located in a suitable region within the pixel.

The storage diode region 1621, the first capacitor region 1625, and the second capacitor region 1617 may be regions for storing charges.

A first transmission transistor region 1611 may be adjacent to the photoelectric element disposed in the lower portion.

A third transmission transistor region 1613 may be disposed on a first side of the first transmission transistor region 1611, and a first switch transistor region 1619 may be disposed on a second side of the first transmission transistor region 1611.

In an embodiment, the storage diode region 1621 may be disposed to be apart from the first switch transistor region 1619. The storage diode region 1621 may be disposed through a DTI process. Accordingly, the storage diode region 1621 may be disposed to be separate from the first switch transistor region 1619.

A second switch transistor region 1623 may be disposed to be apart from the first switch transistor region 1619. In addition, the first capacitor region 1625 may be disposed to be adjacent to the second switch transistor region 1623. For example, based on the first switch transistor region 1619, the first transmission transistor region 1611 may be disposed on a first side, the second switch transistor region 1623 may be disposed on a second side, and the storage diode region 1621 may be disposed on a third side.

The first transmission control signal may be applied to a first transmission gate electrode located in an upper portion of the first transmission transistor region 1611 such that a transfer path of the photo charges generated by the photoelectric element region 1609 may be located in the lower portion of the first transmission gate electrode. In an embodiment, when the first switch control signal SW1 of an enable level is applied to an electrode of the first switch transistor region 1619, photo charges may be transferred in the storage diode region 1621 via the first switch transistor region 1619.

Meanwhile, when the second switch control signal SW2 of an enable level is applied to an electrode of the second switch transistor region 1623, photo charges may be transferred from the first switch transistor region 1619 to the first capacitor region 1625 via the second switch transistor region 1623, without being transferred to the storage diode region 1621. Accordingly, the storage diode region 1621 of a larger area may be secured.

In another embodiment, when the third transmission control signal TG3 of an enable level is applied to an electrode of a third transistor region 1613, photo charges may be transferred to a floating diffusion region (not shown) via the third transmission transistor region 1613. Thereafter, when the gain control signal DRG is applied to an electrode of the gain control transistor region 1615, the photo charges transferred to the floating diffusion region may be transferred to the second capacitor region 1617.

As shown in FIG. 16, a light blocking layer 1627 may be located on the storage diode region 1621. In an embodiment, the light blocking layer 1627 may be disposed on the second surface 1310b of the first substrate 1310. The light blocking layer 1627 may include at least one metal material of, for example, tungsten, aluminum, titanium, ruthenium, cobalt, nickel, copper, gold, silver, or platinum. In this regard, referring to FIG. 13 together, the light blocking layer 1627 may be located at the same level as the conductive pattern 1361. Accordingly, the light leakage phenomenon, in which light leaks through an edge of the pixel and may be incident on the storage diode region 1621 may be prevented.

Meanwhile, although FIG. 16 illustrates that the pixel includes the storage diode region 1621, the present disclosure is not limited thereto, and a storage gate region may be located instead of the storage diode region 1621.

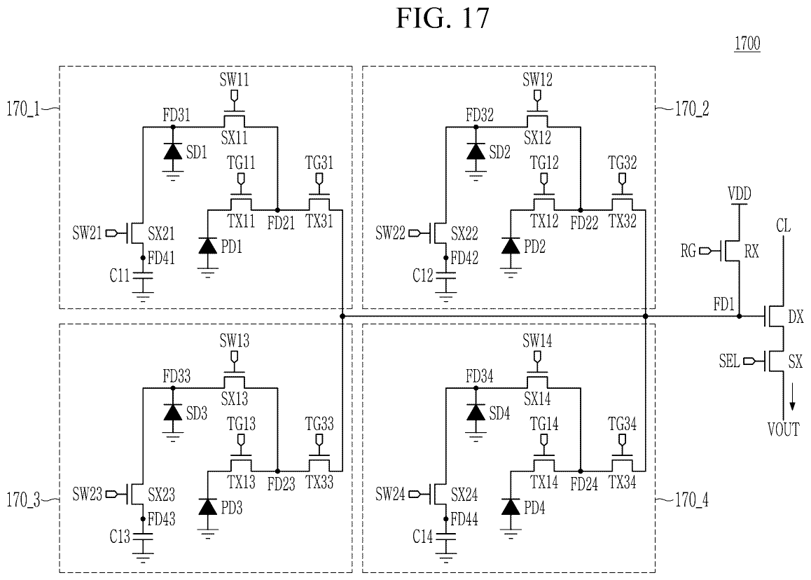

FIG. 17 is a circuit diagram of a pixel according to an embodiment.

Referring to FIG. 17, a pixel 1700 may include a first pixel 170_1, a second pixel 170_2, a third pixel 170_3, and a fourth pixel 170_4.

First to fourth sub-pixels 170_1 to 170_4 may be arranged in rows and columns inside the pixel 1700. The first sub-pixel 170_1 and the second sub-pixel 170_2 may be located in the same row. The third sub-pixel 170_3 and the fourth sub-pixel 170_4 may be located in the same row. The first sub-pixel 170_1 and the third sub-pixel 170_3 may be located in the same column. The second sub-pixel 170_2 and the fourth sub-pixel 170_4 may be located in the same column.

The first sub-pixel 170_1 may include a first photoelectric element PD1. The first photoelectric element PD1 may variably generate photo charges depending on the intensity of light. The photo charges generated by the first photoelectric element PD1 may be transmitted to and accumulated in at least one of floating diffusion nodes FD1, FD21, FD31, and FD41. Although not shown in FIG. 17, in each of the floating diffusion nodes FD1, FD21, FD31, and FD41, a parasitic capacitor (not shown) may be formed, or an actual capacitor element may be connected thereto.

In addition, the first sub-pixel 170_1 may include a plurality of transistors, for example a first transmission transistor TX11, a third transmission transistor TX31, a first switch transistor SX11, a second switch transistor SX21, and a first capacitor C11. Control signals TG11, TG31, SW11, and SW21 may be applied to the first sub-pixel 170_1. In an embodiment, the control signals may be generated by the row driver 130 (refer to FIG. 1).

The first transmission transistor TX11 may be connected between the photoelectric element PD and a floating diffusion node FD21. The first transmission transistor TX11 may be controlled by the first transmission control signal TG11. When the first transmission transistor TX11 is turned on, the charge generated by the photoelectric element PD may be transferred to the floating diffusion node FD21.

The third transmission transistor TX31 may be connected between the floating diffusion node FD21 and the first floating diffusion node FD1. The third transmission transistor TX31 may be controlled by the third transmission control signal TG31. When the third transmission transistor TX31 is turned on, the charges accumulated in the floating diffusion node FD21 may be transferred to the first floating diffusion node FD1.

The first switch transistor SX11 may be connected between the first floating diffusion node FD1 and a floating diffusion node FD31. In response to a first switch control signal SW11, the first switch transistor SX11 may be turned on or turned off, and may interconnect the floating diffusion node FD21 and the floating diffusion node FD31.

The storage diode SD1 may be located in the floating diffusion node FD31. The storage diode SD1 may be a charge storage element capable of storing the photo charges generated by the photoelectric element PD1 before transferring it to a floating diffusion node FD41. The cathode of the storage diode SD1 may become a storage diode region. In an embodiment, the storage diode SD1 may be additionally located within the semiconductor substrate. In an embodiment, the storage diode SD1 may store a part of photo charges generated by the photoelectric element PD.

The second switch transistor SX21 may be connected between the floating diffusion node FD31 and the floating diffusion node FD41. In response to a second switch control signal SW21, the second switch transistor SX21 may be turned on or turned off, and may interconnect the floating diffusion node FD31 and the floating diffusion node FD41.

The first capacitor C11 may be connected between the floating diffusion node FD41 and ground power source. The charges generated by the photoelectric element PD1 may be accumulated in the first capacitor C11 through the floating diffusion node FD21, the floating diffusion node FD31, and the floating diffusion node FD41.

The first capacitor C11 may include a lateral overflow integration capacitor (LOFIC).

The second to fourth sub-pixels 170_2 to 170_4 may have a similar structure to the first sub-pixel 170_1. The description with respect to the first sub-pixel 170_1 may also applied to the second to fourth sub-pixels 170_2 to 170_4. The first to fourth sub-pixels 170_1 to 170_4 may be commonly connected to the first floating diffusion node FD1.

In an embodiment, the photo charges generated by a photoelectric element PD11 may be transferred to the first floating diffusion node FD1 through the first transmission transistor TX11 and the third transmission transistor TX31. Since, in order for the photo charges generated by the photoelectric element of each of the plurality of sub-pixels 170_1 to 170_4 to be transferred to the first floating diffusion node FD1, each of the first transmission transistors TX11, TX12, TX13, and TX14 and the third transmission transistors TX31, TX32, TX33, and TX34 must be passed through, the photo charges generated by the photoelectric element of each of the plurality of sub-pixels 170_1 to 170_4 may not be combined with each other.

Meanwhile, the pixel 1700 may include the reset transistor RX, the driving transistor DX, and the selection transistor SX.

The reset transistor RX may be connected between the first floating diffusion node FD1 and the power source voltage line supplying the power source voltage VDD. The reset transistor RX may be controlled by the reset control signal RG. When the reset transistor RX is turned on, the power source voltage VDD may be applied to the first floating diffusion node FD1, and thereby the first floating diffusion node FD1 may be reset.

The gate of the driving transistor DX may be connected to the first floating diffusion node FD1. The first terminal of the driving transistor DX may be connected to the selection transistor SX, and a driving voltage may be applied to a second terminal thereof. The driving transistor DX may operate as a source-follower amplifier with respect to the voltage of the first floating diffusion node FD1. In response to the voltage of the first floating diffusion node FD1, the driving transistor DX may output the pixel signal VOUT to the column line CL through the selection transistor SX.

The selection transistor SX may be connected between the driving transistor DX and the column line CL, and thereby, may be controlled by the selection control signal SEL. When the selection transistor SX is turned on, the pixel voltage VOUT output from the driving transistor DX may be output to the readout circuit 150 (refer to FIG. 1) through the column line CL connected to the selection transistor SX. For example, in the readout operation, when the selection transistor SX is turned on, a pixel signal including the reset control signal corresponding to the reset operation or the image signal corresponding to the charge accumulation operation may be output through the column line CL.

In FIG. 17, although it is illustrated that one pixel 1700 includes four photoelectric elements PD1, PD2, PD3, and PD4, the present disclosure is not limited thereto, and one pixel 1700 may include more photoelectric elements or fewer photoelectric elements.

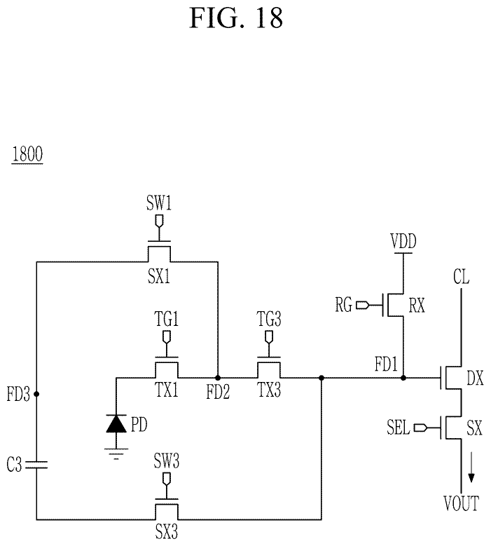

FIG. 18 is a circuit diagram of a pixel according to an embodiment of the present application.

In more detail, FIG. 18 is a circuit diagram of a pixel according to an embodiment of the present application that may be utilized as the pixel PX of FIG. 1.

Referring to FIG. 18, a pixel 1800 may include the photoelectric element PD. The photoelectric element PD may variably generate photo charges depending on the intensity of light. The photo charges generated by the photoelectric element PD may be transmitted to and accumulated in at least one of the first floating diffusion node FD1, the second floating diffusion node FD2, and the third floating diffusion node FD3. Although not shown in FIG. 18, in each of the first floating diffusion node FD1, the second floating diffusion node FD2, and the third floating diffusion node FD3, a parasitic capacitor (not shown) may be formed, or an actual capacitor element may be connected thereto. When the first transmission transistor TX1, the third transmission transistor TX3, and the first switch transistor SX1 are formed to be close to each other, the second floating diffusion node FD2 may be omitted practically.

In addition, the pixel 1800 may include a plurality of transistors, for example the first transmission transistor TX1, the third transmission transistor TX3, the reset transistor RX, the driving transistor DX, the selection transistor SX, the first switch transistor SX1, a third switch transistor SX3, and a third capacitor C3.

Control signals TG1, TG3, RG, SEL, SW1, and SW3 may be applied to the pixel PX. In an embodiment, the control signals may be generated by the row driver 130 (refer to FIG. 1).

The first transmission transistor TX1 may be connected between the photoelectric element PD and the second floating diffusion node FD2. The first transmission transistor TX1 may be controlled by the first transmission control signal TG1. When the first transmission transistor TX1 is turned on, the charge generated by the photoelectric element PD may be transferred to the second floating diffusion node FD2.

The third transmission transistor TX3 may be connected between the second floating diffusion node FD2 and the first floating diffusion node FD1. The third transmission transistor TX3 may be controlled by the third transmission control signal TG3. When the third transmission transistor TX3 is turned on, the charges accumulated in the second floating diffusion node FD2 may be transferred to the first floating diffusion node FD1.

The reset transistor RX may be connected between the first floating diffusion node FD1 and the power source voltage line supplying the power source voltage VDD. The reset transistor RX may be controlled by the reset control signal RG. When the reset transistor RX is turned on, the power source voltage VDD may be applied to the first floating diffusion node FD1, and thereby the first floating diffusion node FD1 may be reset. For example, when the third transmission transistor TX3 is turned on while the reset transistor RX is turned on, the first floating diffusion node FD1 and the second floating diffusion node FD2 may be reset to the power source voltage. When the third switch transistor SX3 is turned on while the reset transistor RX is turned on, the first floating diffusion node FD1 and the third capacitor C3 may be reset to the power source voltage.

The gate of the driving transistor DX may be connected to the first floating diffusion node FD1. The first terminal of the driving transistor DX may be connected to the selection transistor SX, and a driving voltage may be applied to a second terminal thereof. The driving transistor DX may operate as a source-follower amplifier with respect to the voltage of the first floating diffusion node FD1. In response to the voltage of the first floating diffusion node FD1, the driving transistor DX may output the pixel signal VOUT to the column line CL through the selection transistor SX.

The selection transistor SX may be connected between the driving transistor DX and the column line CL, and thereby, may be controlled by the selection control signal SEL. When the selection transistor SX is turned on, the pixel voltage VOUT output from the driving transistor DX may be output to the readout circuit 150 (refer to FIG. 1) through the column line CL connected to the selection transistor SX. For example, in the readout operation, when the selection transistor SX is turned on, a pixel signal including the reset control signal corresponding to the reset operation or the image signal corresponding to the charge accumulation operation may be output through the column line CL.

The first switch transistor SX1 may be connected between the first floating diffusion node FD1 and the third floating diffusion node FD3. In response to the first switch control signal SW1, the first switch transistor SX1 may be turned on or turned off, and may interconnect the second floating diffusion node FD2 and the third floating diffusion node FD3.

A first switch transistor SX1 may be disposed between a first side of the third capacitor C3 and the first floating diffusion node FD1. The third switch transistor SX3 may be disposed between a second side of the third capacitor C3 and the first floating diffusion node FD1. The third capacitor C3 and the third switch transistor SX3 may be coupled in series between the third floating diffusion node FD3 and the first floating diffusion node FD1.

The third capacitor C3 may be connected between the third floating diffusion node FD3 and the third switch transistor SX3. The charges generated by the photoelectric element PD may be accumulated in the third capacitor C3 through the second floating diffusion node FD2 and the third floating diffusion node FD3.

The third capacitor C3 may include a lateral overflow integration capacitor (LOFIC).

The third switch transistor SX3 may be connected between the third capacitor C3 and the first floating diffusion node FD1. In response to a third switch control signal SW3, the third switch transistor SX3 may be turned on or turned off, and may interconnect the third capacitor C3 and the first floating diffusion node FD1.

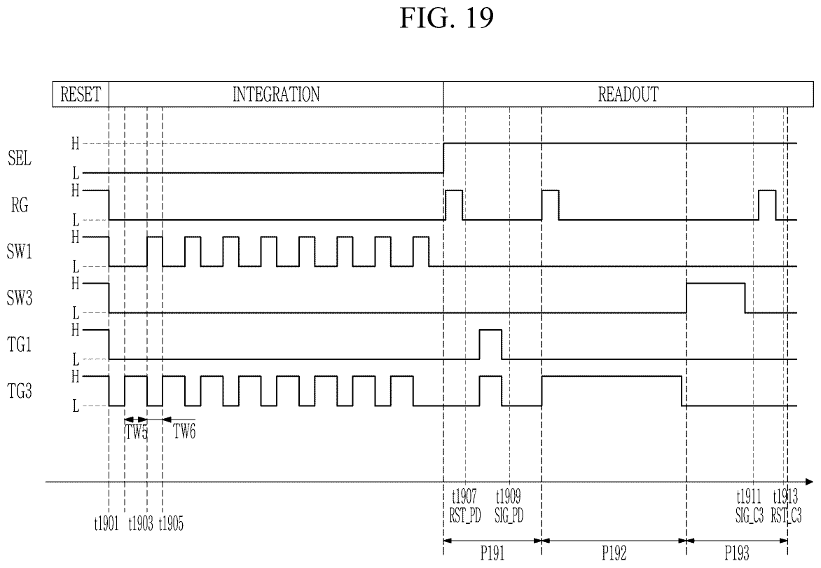

FIG. 19 is a timing diagram showing an operation of a pixel according to FIG. 18.

In FIG. 19, a scan period for driving the plurality of pixels PX on a row line basis may be shown. One scan period may sequentially include the reset period RESET, the integration period INTEGRATION, the readout period READOUT.

In the reset period RESET, charges stored in the first floating diffusion node FD1, the second floating diffusion node FD2, and the third floating diffusion node FD3 may be reset.

In more detail, the reset control signal RG, the first switch control signal SW1, the third switch control signal SW3, the first transmission control signal TG1, and the third transmission control signal TG3 may all have the high-level H. Accordingly, the first floating diffusion node FD1, the second floating diffusion node FD2, and the third floating diffusion node FD3 may all be connected to the power source voltage line providing the power source voltage VDD.

The integration period INTEGRATION is a period in which the photoelectric element PD are exposed to light and thereby charges are generated. In the integration period INTEGRATION, the reset control signal RG, the first switch control signal SW1, the third switch control signal SW3, the first transmission control signal TG1, and the third transmission control signal TG3 may transition from the high-level H to the low-level L. The first switch control signal SW1 and the third transmission control signal TG3 may toggle with a preset period.

In more detail, at t1901, the third transmission control signal TG3 may transition from the low-level L to the high-level H. At t1903, the third transmission control signal TG3 may transition from the high-level H to the low-level L, and the first switch control signal SW1 may transition from the low-level L to the high-level H. At t1905, the third transmission control signal TG3 may transition from the low-level L to the high-level H, and the first switch control signal SW1 may transition from the high-level H to the low-level L. During the integration period INTEGRATION, a first state in which the first switch control signal SW1 is the low-level L and the third transmission control signal TG3 is the high-level H may be maintained during the first period TW5 (i.e., from t1903 to t1901), and a second state in which the first switch control signal SW1 is the high-level H and the third transmission control signal TG3 is the low-level L may be maintained during the second period TW6 (i.e., from t1905 to t1903).

At this time, the row driver 130 (refer to FIG. 1) may adjust the ratio of the first period TW5 and the second period TW6, such that a part of charges generated by the photoelectric element PD may be controlled to be transferred to the third capacitor C3. In an embodiment, the photo charges may be transferred to the third capacitor C3 at a ratio defined by Equation 3 below.

$$TW 6 / ( TW 5 + TW 6 ) \qquad ( Equation 3 )$$

For example, it is assumed that the ratio between the first period TW5 and the second period TW6 is 9:1. Assuming that the photoelectric element PD has generated ten photo charges, one of the photo charges may be transferred to the third capacitor C3. That is, the row driver 130 (refer to FIG. 1) may adjust the ratio of the first period TW5 and the second period TW6, such that an effect similar to adjusting the sensitivity of the pixel 1800 may be obtained.

The first switch transistor SX1 and the third transmission transistor TX3 may be alternately turned on. According to the control of the first switch control signal SW1 and the third transmission control signal TG3, the charges accumulated at the second floating diffusion node FD2 may alternately move to the first switch transistor SX1 and the third transmission transistor TX3. In summary, by controlling the operation of the first switch transistor SX1 and the third transmission transistor TX3, the charge generated by the photoelectric element PD may suitably move to the third capacitor C3 or the first floating diffusion node FD1 via the second floating diffusion node FD2.

The readout period READOUT is a period in which the pixel signal VOUT generated by the pixel 1800 is transferred to the readout circuit 150 (refer to FIG. 1). One readout period READOUT may include a first period P191, a second period P192, and a third period P193. The first period P191 may be a period for performing a CDS operation with respect to the photoelectric element PD. The second period P192 may be a period for performing a reset operation with respect to the overflowed charged in the photoelectric element PD. The third period P193 may be a period for performing a CDS operation with respect to charges overflowed from the photoelectric element PD and stored in the third capacitor C3.

First, the selection control signal SEL may transition from the low-level L to the high-level H. As the selection control signal SEL maintains the high-level H, the pixel 1800 may read the pixel signal VOUT. In addition, the reset control signal RG may transition from the low-level L to the high-level H.

At t1907, a reset signal corresponding to the first floating diffusion node FD1 may be output through the column line CL. That is, at t607, a reset signal RST_PD with respect to the photoelectric element PD may be output as the pixel signal VOUT.

After t1907, the first transmission control signal TG1 and the third transmission control signal TG3 may transition from the low-level L to the high-level H. The photo charges generated by the photoelectric element PD by the first transmission control signal TG1 of the high-level H and the third transmission control signal TG3 of the high-level H may be provided to the first floating diffusion node FD1. Thereafter, the first transmission control signal TG1 and the third transmission control signal TG3 may transition from the high-level H to the low-level L after a preset time.

At t1909, an image signal corresponding to the first floating diffusion node FD1 may be output through the column line CL. That is, at t1909, an image signal SIG_PD with respect to the photoelectric element PD may be output as the pixel signal VOUT.

In the second period P192, the reset control signal RG and the third transmission control signal TG3 may transition from the low-level L to the high-level H. By the reset control signal RG of the high-level H and the third transmission control signal TG3 of the high-level H, the charges accumulated in the first floating diffusion node FD1 and the second floating diffusion node FD2 may be reset to the power source voltage. After a preset time, the reset control signal RG first transitions from the high-level H to the low-level L, and the third transmission control signal TG3 may transition from the high-level H to the low-level L.

In the third period P193, the third switch control signal SW3 may transition from the low-level L to the high-level H. According to the third switch control signal SW3 of the high-level H, the charges accumulated in the third capacitor C3 may be provided to the first floating diffusion node FD1.

At t1911, an image signal SIG_C3 corresponding to the charges accumulated in the third capacitor C3 may be output as the pixel signal VOUT.

After t1911, the reset control signal RG may transition to the high-level H. At this time, the first switch control signal SW1, the third switch control signal SW3, the first transmission control signal TG1, and the third transmission control signal TG3 may maintain the low-level L. According to the reset control signal RG of the high-level H, the first floating diffusion node FD1 may be reset to the power source voltage. Thereafter, the reset control signal RG may transition to the low-level L.

At t1913, a reset signal corresponding to the reset first floating diffusion node FD1 may be output through the column line CL. That is, at t1913, a reset signal RST_C3 corresponding to the charges accumulated in the third capacitor C3 may be output as the pixel signal VOUT.

In summary, the charges accumulated in the third capacitor C3 may be connected to the first floating diffusion node FD1 without passing through pluralities of floating diffusion nodes FD2 and FD3. Accordingly, the pixel 1800 may more accurately sense the charges accumulated in the third capacitor C3.

The configuration of the third switch transistor SX3 directly providing the charges accumulated in the third capacitor C3 to the first floating diffusion node FD1 as shown in FIG. 18 (with reference to FIG. 19) may also be applied to the pixel according to FIG. 5, FIG. 10, and FIG. 17 described-above. For example, the pixel according to FIG. 5, FIG. 10, and FIG. 17 may be configured such that the storage diode SD and the storage gate transistor SG may each, respectively, provide their accumulated charges to the first floating diffusion node FD1.

Meanwhile, in FIG. 19, although it is described that a plurality of transistors are enabled when a signal of the high-level H is applied, the present disclosure is not limited thereto, and an arbitrary transistor may be configured to be enabled when a signal of the low-level L is applied.

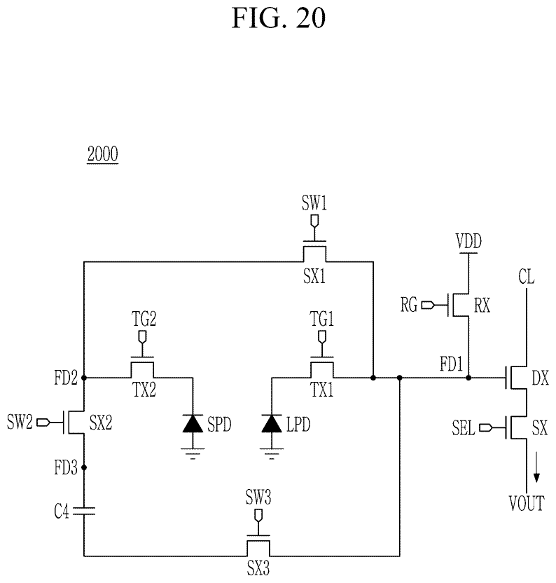

FIG. 20 is a circuit diagram of a pixel according to an embodiment of the present application.

In more detail, FIG. 20 is a circuit diagram of the pixel PX of FIG. 1. Referring to FIG. 20, the pixel 2000 may include a plurality of photoelectric elements, for example, a small photoelectric element SPD and a large photoelectric element LPD. The pixel 2000 may include a plurality of transistors, for example the first transmission transistor TX1, the second transmission transistor TX2, the reset transistor RX, the driving transistor DX, the selection transistor SX, the first switch transistor SX1, the second switch transistor SX2, the third switch transistor SX3, and a fourth capacitor C4. Control signals TG1, TG2, RG, SEL, SW1, SW2, and SW3 may be applied to the pixel 2000. In an embodiment, the control signals may be generated by the row driver 130 (refer to FIG. 1).

The large photoelectric element LPD and the small photoelectric element SPD may variably generate photo charges depending on the intensity of light. For example, the large photoelectric element LPD and the small photoelectric element SPD may generate charges, that is, electrons with a negative charge and holes with a positive charge, in proportion to the amount of indent light. The photo charges generated by the large photoelectric element LPD and the small photoelectric element SPD may be transmitted to and accumulated in at least one of the first floating diffusion node FD1, the second floating diffusion node FD2, and the third floating diffusion node FD3. Although not shown in FIG. 20, in each of the first floating diffusion node FD1, the second floating diffusion node FD2, and the third floating diffusion node FD3, a parasitic capacitor (not shown) may be formed, or an actual capacitor element may be connected thereto.

The first transmission transistor TX1 may be connected between the large photoelectric element LPD and the first floating diffusion node FD1. The first transmission transistor TX1 may be controlled by the first transmission control signal TG1. When the first transmission transistor TX1 is turned on, the charge generated by the large photoelectric element LPD may be transferred to the first floating diffusion node FD1.

The second transmission transistor TX2 may be connected between the small photoelectric element SPD and the second floating diffusion node FD2. The second transmission transistor TX2 may be controlled by the second transmission control signal TG2. When the second transmission transistor TX2 is turned on, the charge generated by the small photoelectric element SPD may be transferred to floating diffusion node FD2.

The reset transistor RX may be connected between the first floating diffusion node FD1 and the power source voltage line supplying the power source voltage VDD. The reset transistor RX may be controlled by the reset control signal RG. When the reset transistor RX is turned on, the power source voltage VDD may be applied to the first floating diffusion node FD1, and thereby the first floating diffusion node FD1 may be reset. When the switch transistor SW1 is turned on while the reset transistor RX is turned on, the first floating diffusion node FD1 and the second floating diffusion node FD2 may be reset to the power source voltage.

The gate of the driving transistor DX may be connected to the first floating diffusion node FD1. The first terminal of the driving transistor DX may be connected to the selection transistor SX, and a driving voltage may be applied to a second terminal thereof. The driving transistor DX may operate as a source-follower amplifier with respect to the voltage of the first floating diffusion node FD1. In response to the voltage of the first floating diffusion node FD1, the driving transistor DX may output the pixel signal VOUT to the column line CL through the selection transistor SX.

The selection transistor SX may be connected between the driving transistor DX and the column line CL, and thereby, may be controlled by the selection control signal SEL. When the selection transistor SX is turned on, the pixel voltage VOUT output from the driving transistor DX may be output to the readout circuit 150 (refer to FIG. 1) through the column line CL connected to the selection transistor SX. For example, in the readout operation, when the selection transistor SX is turned on, a pixel signal including the reset control signal corresponding to the reset operation or the image signal corresponding to the charge accumulation operation may be output through the column line CL.

The first switch transistor SX1 may be connected between the first floating diffusion node FD1 and the second floating diffusion node FD2. In response to the first switch control signal SW1, the first switch transistor SX1 may be turned on or turned off, and may interconnect the first floating diffusion node FD1 and the second floating diffusion node FD2.

The second switch transistor SX2 may be connected between the second floating diffusion node FD2 and the third floating diffusion node FD3. In response to the second switch control signal SW2, the second switch transistor SX2 may be turned on or turned off, and may interconnect the second floating diffusion node FD2 and the third floating diffusion node FD3.

The fourth capacitor C4 and the third switch transistor SX3 may be coupled in series between the third floating diffusion node FD3 and the first floating diffusion node FD1.

The fourth capacitor C4 may be connected between the third floating diffusion node FD3 and the third switch transistor SX3. The charges generated by the small photoelectric element SPD may be accumulated in the third capacitor C3 through the second floating diffusion node FD2 and the third floating diffusion node FD3.

The third capacitor C3 may include a lateral overflow integration capacitor (LOFIC).

The third switch transistor SX3 may be connected between the third capacitor C3 and the first floating diffusion node FD1. In response to the third switch control signal SW3, the third switch transistor SX3 may be turned on or turned off, and may interconnect the third capacitor C3 and the first floating diffusion node FD1.

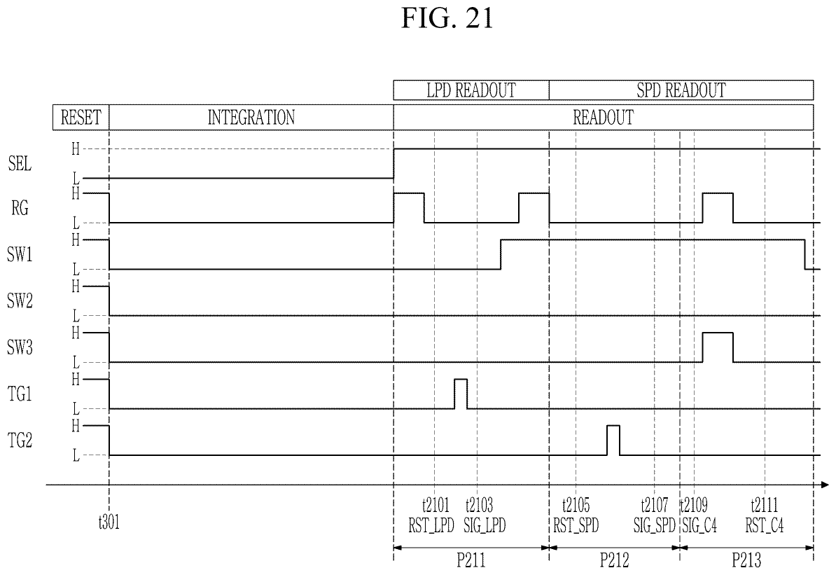

FIG. 21 is a timing diagram showing an operation of a pixel according to FIG. 20.

In FIG. 21, a scan period for driving the plurality of pixels PX on a row line basis may be shown. One scan period may sequentially include the reset period RESET, the integration period INTEGRATION, the readout period READOUT.

In the reset period RESET, the charges stored in the first floating diffusion node FD1, the second floating diffusion node FD2, and the third floating diffusion node FD3 are reset.

In more detail, the reset control signal RG, the first switch control signal SW1, the second switch control signal SW2, the third switch control signal SW3, the first transmission control signal TG1, and the third transmission control signal TG3 may all have the high-level H. Accordingly, the first floating diffusion node FD1, the second floating diffusion node FD2, and the third floating diffusion node FD3 may all be connected to the power source voltage line providing the power source voltage VDD.

The integration period INTEGRATION is a period in which the small photoelectric element SPD and the large photoelectric element LPD are exposed to light and thereby charges are generated. In the integration period, the reset control signal RG, the first switch control signal SW1, the second switch control signal SW2, the third switch control signal SW3, the first transmission control signal TG1, and the third transmission control signal TG3 may transition from the high-level H to the low-level L.

After a preset time, the selection control signal SEL may transition from the low-level L to the high-level H. As the selection control signal SEL maintains the high-level H, the pixel 200 may read the pixel signal VOUT.

The readout period READOUT is a period in which the pixel signal VOUT generated by the pixel 200 is transferred to the readout circuit 150 (refer to FIG. 1). One readout period READOUT may include the LPD readout period LPD READOUT for reading out the pixel signals corresponding to the large photoelectric element LPD and the SPD readout period SPD READOUT for reading out pixel signals corresponding to the small photoelectric element SPD.

The LPD readout period LPD READOUT may include a first period P211. The first period P211 may be a period for performing a DCG operation with respect to the large photoelectric element LPD.

First, after the selection control signal SEL transitions to the high-level H, the reset control signal RG may transition from the low-level L to the high-level H. According to the reset control signal RG of the high-level H, the first floating diffusion node FD1 may be reset to the power source voltage. Thereafter, the reset control signal RG may be transitioned to the low-level L.

At t2101, a reset signal corresponding to the reset first floating diffusion node FD1 may be output through the column line CL. That is, at t2101, a reset signal RST_LPD with respect to the large photoelectric element LPD may be output as the pixel signal VOUT.

After t2101, the first transmission control signal TG1 may transition from the low-level L to the high-level H. The first transmission control signal TG1 of the high-level H may be applied to the gate of the transmission transistor TX1 such that the charges generated by the large photoelectric element LPD may be provided to the first floating diffusion node FD1.

At t2103, an image signal corresponding to the first floating diffusion node FD1 may be output through the column line CL. That is, at t2103, an image signal SIG_LPD with respect to the large photoelectric element LPD may be output as the pixel signal VOUT. After t2103, the first switch control signal SW1 may transition from the low-level L to the high-level H. After a preset time, the reset control signal RG may transition from the low-level L to the high-level H. The first switch control signal SW1 and according to the reset control signal RG of the high-level H, the first floating diffusion node FD1 and the second floating diffusion node FD2 may be reset. Accordingly, after outputting the pixel signals of the large photoelectric element LPD, the charges remaining in the first floating diffusion node FD1 and the charges overflowed from the small photoelectric element SPD to the second floating diffusion node FD2 may be removed. Thereafter, the reset control signal RG may be transitioned to the low-level L.

The SPD readout period SPD READOUT may include a second period P213 and a third period P213. The second period P213 may be a period for performing a CDS operation with respect to the small photoelectric element SPD. The second period P213 may be a period for performing a CDS operation with respect to overflowed charges with respect to the small photoelectric element SPD.

At t2105, a reset signal corresponding to the reset first floating diffusion node FD1 and the second floating diffusion node FD2 may be output through the column line CL. That is, at t2105, the reset signal RST of the small photoelectric element SPD may be output as the pixel signal VOUT.

After t2105, the second transmission control signal TG2 may transition from the low-level L to the high-level H. The second transmission control signal TG2 of the high-level H may be applied to the gate of transmission transistor TX2 such that the charges generated by the small photoelectric element SPD may be provided to the first floating diffusion node FD1 and the second floating diffusion node FD2. After a preset time, the second transmission control signal TG2 may transition to the low-level L.

At t2107, an image signal corresponding to the first floating diffusion node FD1 and the second floating diffusion node FD2 may be output through the column line CL. That is, at t2107, the image signal SIG with respect to the small photoelectric element SPD may be output as the pixel signal VOUT.

After t2107, the third switch control signal SW3 may transition from the low-level L to the high-level H. According to the third switch control signal SW3 of the high-level H, the charges accumulated in the fourth capacitor C4 may be provided to the first floating diffusion node FD1.

Meanwhile, the charge overflowed from the small photoelectric element SPD by the exposure operation may be accumulated in the fourth capacitor C4. At t2109, an image signal SIG_C4 corresponding to the fourth capacitor C4 may be output through the column line CL. That is, at t2107, the output pixel signal is the image signal SIG_C4 with respect to overflowed charges of the small photoelectric element SPD.

After t2109, the reset control signal RG may transition from the low-level L to the high-level H. In addition, the third switch control signal SW3 may also transition from the low-level L to the high-level H. At this time, the first floating diffusion node FD1 may be reset to the power source voltage. Thereafter, the reset control signal RG may transition to the low-level L.

According to the reset control signal RG of the high-level H, the first floating diffusion node FD1 may be reset to the power source voltage. Thereafter, the reset control signal RG may transition to the low-level L.

At t2111, a reset signal corresponding to reset the first floating diffusion node FD1 may be output through the column line CL. That is, at t2111, a reset signal RST_C4 corresponding to the charges accumulated in the fourth capacitor C4 may be output as the pixel signal VOUT.

In summary, the charges accumulated in the fourth capacitor C4 may be connected to the first floating diffusion node FD1 without passing through the pluralities of floating diffusion nodes FD2 and FD3. Accordingly, a pixel 2000 may more accurately sense the charges accumulated in the fourth capacitor C4.

Meanwhile, in FIG. 21, although it is described that a plurality of transistors are enabled when a signal of the high-level H is applied, the present disclosure is not limited thereto, and an arbitrary transistor may be configured to be enabled when a signal of the low-level L is applied.

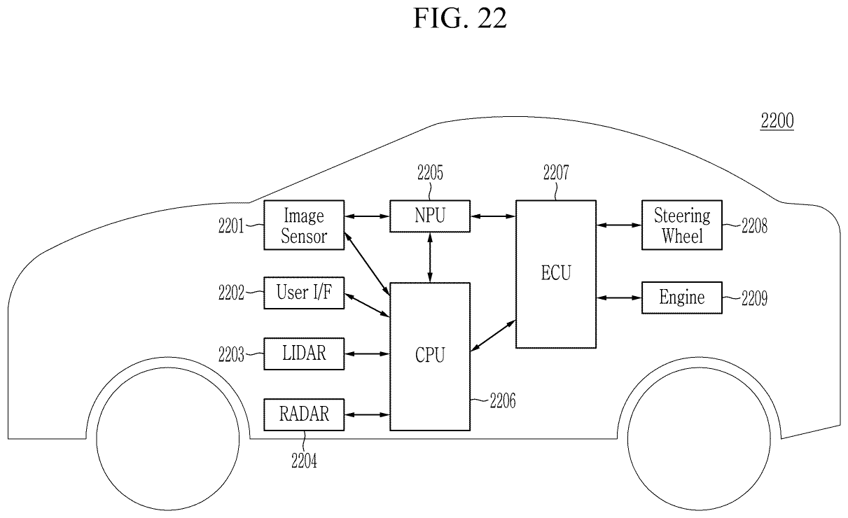

FIG. 22 is a block diagram showing a vehicle according to an embodiment.

As shown in FIG. 22, a vehicle 2200 may include an image sensor 2201, a user interface 2202, a Light Detection And Ranging (LIDAR) sensor 2203, a Radio Detection And Ranging (RADAR) sensor 2204, a neural processing unit (NPU) 2205, a CPU 2206, and an ECU 2207, and the ECU 2207 may receive the steering angle of the vehicle and the speed of the vehicle from a steering wheel 2208 and an engine 2209. Besides, although not shown in the drawing, the vehicle 2200 may further include a communication module, an input/output module, a security module, a power control device, and the like, and may also further include various types of control devices.

Here, the image sensor 2201 may be an image sensor described with reference to FIGS. 1 and FIGS. 5-21.

In an embodiment, the vehicle 2200 may detect objects, using information on the external environment acquired through the sensors (for example, the image sensor 2201, the LIDAR sensor 2203, and/or the RADAR sensor 2204). The sensors 2201, 2203, and 2204 may image an object, measure a distance to the object, and transmit it to processors (e.g., the CPU 2206, a NPU 2205 and the ECU 2207). In order for the sensors 51, 53, and 54 to detect objects, besides the above-described sensors, ToF (Time of Flight) sensors, ultrasonic sensors, infrared sensors, geomagnetic sensors, position sensors (e.g., GPS), acceleration sensors, atmospheric pressure sensors, temperature/humidity sensors, proximity sensors, gyroscope sensors, and so on may be further used.

The image sensor 2201 may provide image or optical sensing, and may, for example, a CMOS (complementary metal-oxide-semiconductor) image sensor. The image sensor 2201 may acquire image or visual information on objects. For example, the image sensor 2201 may be attached to the front of the vehicle to capture driving images or measure the distances to objects located in front of the vehicle, etc. The position at which the image sensor 2201 is attached is not limited thereto, and the image sensor may be attached at various positions to accomplish the intended purpose of obtaining information on objects.

The image sensor 2201 may image an environment surrounding the vehicle 2200. The vehicle 2200 may include at least two image sensors to capture images of the full 360-degree view of the vehicle's surroundings. In an embodiment, the image sensor 2201 may include a wide-angle lens. In an embodiment, the vehicle 2200 may include four image sensors for the front, rear, left, and right sides of the vehicle; however, the present invention is not limited thereto, the single image sensor 2201 may capture images of the environment around the vehicle. The image sensor 2201 may continuously capture images of the vehicle's surroundings to continuously provide information on the vehicle's surroundings to the vehicle 2200.

The image sensed by the image sensor 2201 may be processed by the CPU 2206 and/or the NPU 2205. The CPU 2206 may process the sensed images in a motion-based manner to detect objects, and the NPU 2205 may process the sensed images in a shape-based manner to detect objects. The image sensor 2201 may be attached to the front of the vehicle to sense the external environment in front of the vehicle; however, it is not limited thereto, and may be attached to various surfaces of the vehicle to sense the external environment.

Here, the image sensor 2201 may include a single photoelectric element and transfer photo charges generated in a high-illuminance environment to a plurality of floating diffusion nodes. For example, the image sensor 2201 may adjust the sensitivity by transferring a fractional photo charges of a preset ratio among photo charges generated in the high-illuminance environment to the separate floating diffusion node.

Meanwhile, the conventional image sensor includes a plurality of photoelectric elements, that is, a photoelectric element operating in a high-illuminance environment and a photoelectric element operating in a low-illuminance environment, and thereby optical problems such as discrepancy in relative illumination and color separation was caused. However, the image sensor 2201 may include a single photoelectric element, such that the optical problem may be solved.

The user interface 2202 may include various electronic devices and mechanical devices included in the driver's seat, the passenger's seats, and so on, such as the vehicle's instrument panel, a display indicating driving information, a navigation device, an air conditioning system, etc.

The LIDAR sensor 2203 may measure the distances to target objects by emitting a laser pulse and receiving the echoes of the laser pulse from the objects. The LIDAR sensor 2203 may typically include a laser, a scanner, a receiver, and a positioning system. For the laser, light in the wavelength range of 600 nm to 1000 nm is generally used, but the wavelength range may differ depending on the laser's use. The scanner may scan the sensed surrounding environment to quickly acquire information on the surrounding environment, and there may be several forms of scanners using a plurality of mirrors. The receiver may receive the laser pulses reflected from target objects, and sense and amplify photons from the laser pulses. The positioning system may check out the location coordinates and direction of the device equipped with the receiver, to realize three-dimensional images. The LIDAR sensor 2203 and the RADAR sensor 2204 may be differentiated according to their effective measurement distances.

The RADAR sensor 2204 may emit an electromagnetic wave and receive the echoes of the electromagnetic wave from target objects, to measure the distances to the objects or identify the objects, or measure the locations and moving speeds of the objects, etc. The RADAR sensor 2204 may include a transmitter and a receiver. The transmitter may generate and output an electromagnetic wave, and the receiver may receive the echoes from target objects and process the signals. The RADAR sensor 2203 may perform transmission and reception through one antenna, but is not limited thereto. The electromagnetic wave frequency band which is used in the RADAR sensor 2204 may be a radio wave band or a micro wave band, but may be changed depending on its purpose. In an embodiment, the LIDAR sensor 2203 and the RADAR sensor 2204 may be attached to the vehicle to assist in determining the relative positional relationship between the vehicle and objects of interest. The RADAR sensor 2204 may be categorized as a long radar sensor or a short radar sensor.

The NPU 2205 may receive input data, and perform computations using an artificial neural network, and provide output data based on the computation results. The NPU 2205 may be a processor optimized for simultaneous matrix operations, and be able to process multiple computations in real time, and derive optimal values by self-learning based on accumulated data. The NPU 2205 is optimized for simultaneous matrix calculation thereby capable of processing multiple operations in real time, and may learn on its own based on accumulated data to derive local-maximum values from current driving parameters.

In an embodiment, the NPU 2205 may be a specialized processor to execute a deep-learning type algorithm. For example, the NPU 2205 may be a specialized processor to perform a deep-learning algorithm. For example, the NPU 2205 is capable of calculation based on various types of network, such as convolution neural network (CNN), region-based convolution neural network (R-CNN), region proposal network (RPN), recurrent neural network (RNN), Fully Convolutional Network, long short-term memory (LSTM) Network, Classification Network, or the like. However, the NPU is not limited thereto, and may be capable of various kinds of arithmetic processing simulating human neutral networks.

The NPU 2205 may receive driving images from the image sensor 2201, and perform shape-based object detection based on the driving images. The NPU 2205 may identify each of a plurality of objects in the driving images by extracting the features of the plurality of objects and performing self-learning based on the accumulated data. For example, the NPU 2205 may extract objects serving as criteria for driving, such as vehicles, pedestrians, traffic lights, lanes, etc., even from a single driving image, on the basis of the features determined using the accumulated data as learning materials.

The CPU 2206 may control an overall operation of the vehicle 2200. The CPU 2206 may include a single processor core, or may include multiple processor cores. The CPU 2206 may process or execute programs and/or data stored in the memories. For example, the CPU 2206 may control the functions of the NPU 2205 and the ECU 2207 by executing programs stored in the memories.

The CPU 2206 may acquire the steering angle and the vehicle speed from the ECU 2207. The steering angle may be determined by the driver's operation on the steering wheel 2208, and be processed by the ECU 2207 controlling the operation of a steering control unit, and be provided to the CPU 2206. The vehicle speed may be measured based on at least one of the driver's pedaling (e.g., the operation on the accelerator), the rotational speed of the engine 2209, and the wheel speed measured by wheel sensors, and may be processed in the ECU 2207 controlling the vehicle speed and be provided to the CPU 2206.

Further, the CPU 2206 may determine the relative position relationship between the vehicle and the surrounding vehicles, and may issue a command to maintain the number of revolutions of the engine 2209 for cruising to maintain a certain distance from a surrounding vehicle according to a predetermined driving plan, and may issue a command to adjust the steering wheel 2208 to the left or right to change the steering angle, to perform an evasive maneuver when the vehicle and the surrounding vehicle are below a threshold distance, or when the surrounding vehicle cuts in. In FIG. 22, the steering wheel 2208 and the engine 2209 are shown as components related to the steering angle and the vehicle speed; however, the present invention is not limited thereto, and the steering angle and the vehicle speed may be determined through various vehicle components.

The CPU 2206 may perform object detection on driving images in a motion-based manner. The motion-based manner is a method of detecting the degree of motion of an object over time to determine its relative motion. Driving images may be consecutively acquired in units of a frame through the image sensor 2201. For example, individual frames may be acquired at a rate of 60 fps (frames per second). In this case, the CPU 2206 may detect motions over time between image frames acquired every 1/60 seconds. In the motion-based manner, optical flow which refers to the distribution of motion vectors of an object, and so on may be included.

The CPU 2206 may use the distances to objects acquired from the LIDAR sensor 2203 and the RADAR sensor 2204 other than the image sensor 2201, to maintain a stable driving state of the vehicle. Further, the CPU 2206 may issue commands to adjust the conditions inside and outside the vehicle, in response to driver's operations on the user interface 2202.

The ECU 2207 may be an electronic control unit provided to control the overall operation or a part of the operation of the vehicle. The ECU 2207 may control the operation of the vehicle according to parameters of the vehicle based on the operation of a combustion engine, the operation of one or more electric motors, a semi-automatic gearbox (SAGB) or an automatic gearbox (AGB), and other driver's control, through a CAN (controller area network) multiplexing bus.

The ECU 2207 may electronically control the vehicle's engine, the actuator of the steering control device, the shift control system, the anti-lock brake system, the airbag control system, and the like, by a computer, and may provide the vehicle speed based on the rotational speed of the engine or the wheel speed measured by a wheel sensor, to the vehicle 2200, and may provide the steering angle of the vehicle from the steering control device to the vehicle 2200.

In an embodiment, the ECU 2207 may control the states of the steering wheel 2208 and the engine 2209 in response to commands issued by the CPU 2206 and the NPU 2205. In an embodiment, the ECU 2207 may accelerate or decelerate the vehicle in response to commands issued by the CPU 2206 and NPU 2205, and may provide a signal to the engine 2209 to increase or decrease the rotational speed of the engine for acceleration or deceleration. Further, the ECU 2207 may adjust the steering wheel 2208 to the left or right for an evasive maneuver according to a predetermined driving plan, when the distance to a surrounding vehicle is below a threshold distance, or when a surrounding vehicle cuts in.

According to an embodiment of this disclosure, the CPU 2206 or the ECU 2207 may check defects in a ramp signal RML to turn off the autonomous driving mode of the vehicle 2200. For example, the CPU 2206 or the ECU 2207 may detect a defect in the ramp signal RML while the vehicle is running in the autonomous driving mode based on the image sensor 2201, and immediately change the driving mode from the autonomous driving mode to the manual driving mode by the driver, such that the safety of the user is secured. For example, the vehicle 2200 may detect a defect in the ramp signal RML, and stop the driving assistance function based on the ramp signal RML, such that the safety of the driver or the user is secured.

In the drawing, it is shown that the ECU 2207 is provided separately from the CPU 2206 in the vehicle; however, the present invention is not limited thereto, and the vehicle control function of the ECU 2207 may be given to the CPU 2206 and be performed in the CPU, and in this case, the CPU 2206 may be understood as having at least two processor cores. In FIG. 22, it is shown that the ECU 2207 is a separate component from the CPU 2206; however, it is not limited thereto, and may be included in the CPU 2206.

Although not shown in FIG. 22, the vehicle 2200 may further include a communication module. The communication module may transmit and receive data to and from the outside of the vehicle 2200. For example, the communication module may perform communication with objects outside the vehicle 2200. In this case, the communication module may perform communication in the V2X (Vehicle to Everything) manner. For example, the communication module may perform communication in the V2V (Vehicle to Vehicle) manner, the V2I (Vehicle to Infra) manner, the V2P (Vehicle to Pedestrian) manner, and the V2N (Vehicle to Nomadic Devices) manner. However, the communication module is not limited thereto, may transmit and receive data in various well-known communication manners. For example, the communication module performs communication by using, for example, 3G, 4G (LTE), 5G, Wi-Fi, Bluetooth, Bluetooth Low Energy (BLE), Zigbee, near-field communication (NFC), and ultrasonic communication methods, or the like, and may include both short-distance and long-distance communication.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An image sensor, comprising:
a pixel including
a photoelectric element configured to generate photo charges,
a driving transistor configured to generate a pixel signal based on a voltage of a first node connected to the photoelectric element,
a charge storage element connected to the photoelectric element and configured to store the photo charges,
a second transmission transistor connected between the first node and a second node,
a first transmission transistor connected between the second node and the photoelectric element, and
a first switch transistor connected between the second node and the charge storage element; and
a row driver connected to the pixel and configured to control the pixel.

2. The image sensor of claim 1, wherein the pixel further includes a second switch transistor connected between the charge storage element and a ground power source, and a first capacitor connected between the second switch transistor and the ground power source.

3. The image sensor of claim 2, wherein the first capacitor comprises a lateral overflow integration capacitor (LOFIC).

4. The image sensor of claim 1, wherein the charge storage element is a storage diode or a storage gate transistor.

5. The image sensor of claim 1, wherein:
the pixel further includes a second switch transistor,
the charge storage element is a first capacitor,
the first switch transistor is connected between a first side of the first capacitor and the first node, and
the second switch transistor is connected between a second side of the first capacitor and the first node.

6. The image sensor of claim 1, wherein:
the photoelectric element is configured to generate the photo charges by being exposed to light during a first time period; and
the row driver is configured to control the pixel so as to transfer the photo charges to the charge storage element and the first node during the first time period.

7. The image sensor of claim 6, wherein the row driver is configured to control the pixel, such that, during the first time period, a first operation of turning on the second transmission transistor and turning off the first switch transistor, and a second operation of turning off the second transmission transistor and turning on the first switch transistor are repeated.

8. The image sensor of claim 7, wherein:
the first operation is performed during a first period, and the second operation is performed during a second period; and
photo charges among the photo charges corresponding to a ratio of the second period divided by a sum of the second period and the first period are transferred to the charge storage element.

9. The image sensor of claim 6, wherein the row driver is configured to control the pixel, such that, during the first time period, a signal of a third potential between a first potential for turning on the first switch transistor and a second potential for turning off the first switch transistor is provided to a gate of the first switch transistor, and during the first time period, an operation of turning on the second transmission transistor and an operation of turning off the second transmission transistor are repeated.

10. An image sensor, comprising:
a photoelectric element region in which a photoelectric element configured to generate photo charges by being exposed to light during a first time period is disposed;
a first transmission transistor region disposed in the photoelectric element region and configured to receive the photo charges;
a first selection transistor region configured to receive the photo charges through the first transmission transistor region; and
a third transmission transistor region configured to receive the photo charges through the first transmission transistor region,
wherein, during the first time period, the photo charges are alternately transferred to the first selection transistor region and the third transmission transistor region.

11. The image sensor of claim 10, wherein a gate of the first transmission transistor region comprises a vertical transfer gate.

12. The image sensor of claim 10, further comprising a charge storage element disposed apart from the first selection transistor region in a first direction and configured to store the photo charges,
wherein the charge storage element is separated from the first selection transistor region through a deep trench isolation (DTI).

13. The image sensor of claim 12, wherein a light blocking layer is located on the charge storage element.

14. The image sensor of claim 10, wherein the first selection transistor region and the third transmission transistor region are disposed in a first direction from the first transmission transistor region.

15. The image sensor of claim 14, wherein the third transmission transistor region and the first selection transistor region are spaced apart from each other in a second direction crossing the first direction.

16. The image sensor of claim 10, further comprising:
a second selection transistor region disposed apart from the first selection transistor region in a second direction; and
a first capacitor region disposed apart from the second selection transistor region in the second direction.

17. The image sensor of claim 16, wherein the first capacitor region comprises a lateral overflow integration capacitor (LOFIC).

18. A driving method of an image sensor, the driving method comprising:
alternately performing a first operation of transferring photo charges of a photoelectric element generated during a first period to a charge storage element and a second operation of transferring photo charges of the photoelectric element generated during a second period after the first period to a first node;
generating a first pixel signal based on a voltage of the first node; and
generating a second pixel signal based on a voltage of the charge storage element.

19. The driving method of claim 18, further comprising generating a third pixel signal based on a voltage of a first capacitor connected to the charge storage element and configured to store photo charges overflowing from the photoelectric element.

20. The driving method of claim 18, wherein the generating the first pixel signal comprises generating a third pixel signal based on a voltage of the first node and a voltage of a second capacitor connected to the first node.
